(19) United States
(12) Patent Application Publication
(10) Pub. No.: US 2004/0239345 A1
(43) Pub. Date: Dec. 2, 2004

(54) Measurement of coatings on metal

(76) Inventor: Bijan K. Amini, Houston, TX (US)

Correspondence Address: EM-Tech Sensors LLC, Suite 650, 15832 West Hardy Road, Houston, TX, 77060, US

(21) Appl. No.: 10/137,609

(22) Filed: May 1, 2002

Related U.S. Application Data
(60) Provisional application No. 60/287,887, filed on May 1, 2001.

(51) Int. Cl. G01R 27/08

(52) U.S. Cl. 324/702

(57) ABSTRACT

Oscillating magnetic flux energy is coupled with coated material. The oscillating magnetic energy is used to measure the electrical impedance and magnetic permeability of the material. Using known values of conductivity and permeability, is this possible to measure the extent of diffusion, including concentration, of the coating into the substrate. The method of this invention does not require destructive testing of the target material.

### CROSS REFERENCE TO RELATED APPLICATION

This application claims the benefit of and priority to U.S. Provisional Application No. 60/287,887 entitled “Measurement of Coating on Metal and filed May 1, 2001.

### BACKGROUND OF INVENTION

1. Field of Use

The invention subject of this specification pertains to a method and apparatus for measuring the thickness and diffusion of a coating placed on a metal substrate. This invention may be utilized in determining the properties of the coating placed upon the surface of a substrate, e.g., a plating process. The invention may also be utilized to measure the properties of a coating diffused into a substrate. It is a goal of a diffusion coating process to achieve a deposition of the coating material within the molecular structure of the substrate to minimize de-lamination of the coating.

The invention also measures the depth and concentration of the dispersion of the coating into the substrate. The invention permits the measurement of these properties without destruction of the material. The invention does not require contact between the material being studied or measured and the measuring apparatus. 2. Description of Related Art

There are many examples of metal being coated with other materials. These coating materials may be metallic or non-metallic. These coating materials may be simply deposited on the metal or may be diffused into the metallic surface. Various methods have been employed to test the coating. The test parameters have included the thickness of the coating, the degree of bonding to the surface of the substrate, the dispersion of the coating material into the substrate and the percentage concentration of the coating at various depths of the substrate.

Prior methods of testing have required destructive techniques. These methods have utilized etching into the coating or dissection of a coated material sample to ascertain the thickness achieved. Other methods have required removal of sample materials and measuring the thickness of the coating upon the substrate or measuring the concentration of the dispersed coatings at various depths into the substrate.

Non-destructive methods have utilized ultrasonic testing. It has been found, however, that the thickness of diffused coatings is very difficult or impossible to be determined by ultrasonic methods. This has been experienced because there is no clear line of density demarcation between the coating material and underlying metal. Therefore there is no distinct interface between the coating and substrate, having differing densities, to reflect the sonic energy. Moreover, ultrasonic determination requires direct contact with the object thereby making ultrasonics problematic for uneven surfaces or where rapid measurement is desirable.

### SUMMARY OF INVENTION

The method and apparatus subject of this invention achieves improved measurement of coating dispersion on and into the metal. The invention utilizes electromagnetic (EM) waves; in particular EM waves generated through low impedance coils, which emphasize the waves' magnetic component. The EM sensors are non-contacting, may move rapidly over the material, and do not require a distinct reflective interface.

The EM sensing technique has been demonstrated to achieve improved measurement of the thickness of an electrically conductive metallic coating material, i.e., chrome, placed on carbon steel tubes by known coating diffusion methods. It will be appreciated that carbon steel is both electrically conductive and magnetically permeable. Although the coating discussed in this specification was electrically conductive, it is not required that either the coating or substrate be electrically conductive or magnetically permeable.

The nature of the chromizing diffusion process produces deposition variations axially and azimuthally on the tube. Therefore, an instrument utilized in the measurements of tubes should have a spatial resolution capability of less than one inch for azimuthal measurements. This resolution factor is related to the diameter of the tubing material or other geometric considerations of the subject material. The apparatus of the invention should also have the ability to maintain a sufficient distance from the coated material surface to avoid welds, joints and other protrusions. This configuration will have multiple and obvious benefits.

The method and apparatus may utilize a dc powered or low frequency powered ac system for the purpose of focusing an oscillating or pulsed magnetic field (hereinafter termed “oscillating flux”) containing multiple frequencies and enabling this oscillating flux to penetrate more deeply into the target metal. The deeper penetration of magnetic flux can be accomplished by reducing the magnetic permeability of the substrate, the coating, or both as applicable. It is beneficial to reduce the permeability when the coating or substrate has a permeability greater than one or the coating material is deeply diffused into a magnetically permeable metallic substrate.

For the apparatus utilized in the embodiment of the invention discussed in detail herein, the ac sensor size was designed to be nearly the diameter of the tubing. This insured that the measurements would occur over at least an area the size of the sensor diameter. For smaller sensing areas, the sensor diameter could be reduced proportionately.

The ac system generated a sinusoidal oscillating magnetic flux transmitted into the test sample. This transmitted flux was swept linearly through a band of frequencies. The frequencies maybe generated digitally. The apparatus utilized components capable of digitally generating single or multiple frequencies transmitted to the target material as a pulsed frequency sweep. A number of these pulsed sweeps are averaged together for each data point graphed. These graphs are displayed for amplitude and phase as a function of time and frequency. Thus it is possible to track which frequency contains the most energy and which frequency responds to variations in chrome coating thickness in both amplitude and phase.

### BRIEF DESCRIPTION OF DRAWINGS

The accompanying drawings, which are incorporated in and constitute a part of the specification, illustrate preferred embodiments of the invention. These drawings, together with the general description of the invention given above and the detailed description of the preferred embodiments given below, serve to explain the principles of the invention.

FIG. 1 illustrates a schematic outline of some of the components utilized in the invention for creating the “Metallic Transparency”™ region and transmitting and receiving magnetic flux.

FIG. 2 illustrates an embodiment of the invention whereby an oscillating magnetic flux saturates a target metal sample and a second higher frequency oscillating flux is transmitted into the sample.

FIGS. 3 and 3A illustrate an embodiment of the magnetic saturation generator for penetrating metal with oscillating magnetic flux.

FIGS. 4A through 4D illustrates the magnetic coupling achieved various embodiments of the apparatus of the invention.

FIG. 5 illustrates an embodiment of the apparatus of the invention comprising a saturation flux generator and magnetic flux transmitter and receiver coils placed at the culminator of the saturation flux generator.

FIGS. 6A, 6B, and 6C illustrate alternate configurations of saturation flux poles and penetration achieved into the target metal.

FIG. 7A illustrates a magnetic saturation generator and the saturation flux engaged with the target metal.

FIG. 7B further illustrates the apparatus of shown in 7A.

FIG. 8 illustrates an embodiment with magnetic flux and transmitter nulled to each and integral to the magnetic saturation flux generator.

FIG. 9 illustrates an embodiment of the magnetic saturation core of the invention.

FIG. 9A illustrates a cross sectional view of the magnetic saturation core illustrating one embodiment of the placement of the magnetic saturation coil, magnetic flux transmitter and magnetic flux receiver.

FIG. 9B illustrates a cross section view of another embodiment of the nested receiver and transmitter within the magnetic saturation core.

FIG. 10 illustrates the relationship between the frequency of oscillating magnetic flux and depth of penetration into the target metal.

FIGS. 11A, 11B and 11C illustrate the relationship between the magnetic transmitter flux amplitude (FIG. 11A), the magnetic saturation flux amplitude (FIG. 11B), and the flux receiver signal amplitude (FIG. 11C).

FIG. 12 illustrates the relationship between the flux density and the change in magnetic field intensity H (ΔH) in amp-turns/meter.

FIG. 13 illustrates the relationship between the receiver amplitude A_{Rx} and H in amp-turns/meter.

FIG. 14 is a graph of amplitude versus time for a bistatic configured magnetic saturation flux generator of the present invention coupling with differing metals.

FIG. 15 illustrates the apparatus used in measuring the diffusion of chrome on a steel tubing.

FIG. 16 illustrates an embodiment of the method of practicing the invention showing the sequential steps of the method.

FIG. 17 illustrates a graph of phase measurements for differing diffusion coating samples with de-convoluted frequencies.

FIGS. 18A and 18B illustrate the graph of phase measurements of test samples with all frequencies integrated.

FIG. 19 illustrates an embodiment of the invention utilizing a single transducer coil

FIG. 20 illustrates the apparatus of the invention in conjunction with a sample of coated tubing.

FIG. 21 illustrates measured phase differences for test samples

FIG. 22 illustrates test data for multiple test samples rotated 90° (four readings per sample).

FIG. 23 illustrates the test data in a different format.

FIG. 24 illustrates the test data in a different format.

FIG. 25 illustrates data results from the transducer embodiment utilizing high frequencies.

The above general description and the following detailed description are merely illustrative of the subject invention, and additional modes, advantages, and particulars of this invention will be readily suggested to those skilled in the art without departing from the spirit and scope of the invention.

### DETAILED DESCRIPTION OF THE INVENTION

The apparatus subject of the invention incorporates an alternating current (ac) system generating the oscillating magnetic flux transmitted and permeating into the target and inducing a responsive signal that is detected by the receiver. The apparatus may also incorporate a first direct current (dc) system generating a saturating flux to reduce the permeability of the material substrate and second, the system generating the oscillating magnetic flux transmitted and permeating into the target and inducing the signal detected by the receiver

In simple terms, the invention works in the following steps: (1) a saturation component (a saturation flux generator) containing a “saturation coil”, is preferably wrapped around a highly permeable core (“saturation core”). When the saturation coil is energized with direct current, it becomes an electromagnet. The saturation coil creates one or more fields of magnetic flux (“saturation flux”) through the saturation core and adjacent or near the target metal. The saturation flux engages with the adjacent target metal and creates a partial or full magnetic saturation of the metal proximate to the saturation coil. This induced saturation results in the magnetic permeability of the proximate target metal being substantially lowered. When fully saturated, that portion of the metal cannot absorb further magnetic flux, thereby allowing additional flux to readily penetrate into and possibly through the thickness of the metal. When partially saturated, the metal acquires greater capacity to engage or couple with magnetic flux, especially magnetic flux oscillating at relatively high frequencies. In such a state, that portion of the magnetically permeable material has become “transparent” to magnetic flux. This partially or fully saturated section is known as a “transparency” or a “Metallic Transparency”. (2) One or more magnetic flux transmitter components (“transmitters”), each utilizing one or more coils (“transmitter coil”) located proximate to a Metallic Transparency, then create one or more fields of additional magnetic flux oscillating at frequencies preferably equal to or greater than the saturation flux. This oscillating magnetic flux (“transmitter flux”) is engaged with the section of target metal in full or partial saturation. The saturated regions of the metal have greatly reduced magnetic permeability, thereby allowing the transmitter flux to more readily penetrate into the metal. (3) Electrically conductive media, e.g., metal coating media on the surface of the target metal and the target metal interact with this oscillating magnetic flux. Through basic electromotive forces, a separate oscillating magnetic flux is induced in the electrically conductive media, i.e., the metal substrate and metal coating. (4) The field of this induced magnetic flux extends back to the apparatus. As in step No. 1 above, the same or similar saturation coils create a transparency near a separate coil (“receiver coil”) so that the induced magnetic flux from the target material can be received and measured by this receiver coil. (5) The receiver component, of which the receiver coil is part, converts the induced flux (“receiver signal”) into electrical signals (“receiver current”) that are filtered and processed in order to determine the electrical resistivity of target containing the diffused coating. The receiver signal is electrically processed to concentrate and magnify the induced oscillating magnetic flux, thereby forming the receiver current. The transmitter flux is nulled to minimize direct transmission of flux from the transmitter to the receiver. The transmitter flux is compared to the received signal and, using the changes in amplitude and phase, the electrical resistivity of the target region can be determined and displayed. These signals may then be sent to the output display for further processing, display, and recording. The output display, power supply, and other ancillary equipment may be located separate from the saturation coil and core, the transmitter coil and receiver coil.

Accordingly, the method and apparatus of the invention includes the capability of generating magnetic flux (“saturation flux”) powered by a dc or a relatively low frequency ac current to engage and magnetically saturate a portion of the coated target metal. The saturation may be either partial or complete. A completely magnetically saturated material will be a fully Metallic Transparency region within the coated metal. A full Metallic Transparency region will have a relative permeability of near unity. A partially saturated region will have a significantly reduced relative permeability, but the permeability will still remain above unity and have the capacity to absorb additional magnetic flux.

The invention also includes the capability to generate and transmit one or more oscillating magnetic flux (“transmitter flux”) into or through the Metallic Transparency region (either full or partial) created in the coated metal. The invention also includes the capability to receive and measure any magnetic flux (“receiver signal”) induced in the coated material or metal substrate proximate to the apparatus of the invention.

Since a completely saturated region will constitute a full Metallic Transparency region, the additional oscillating transmitter flux will penetrate through the Metallic Transparency region without impact. Therefore, the transmitter flux may not provide useful information regarding the coating, the substrate or the diffusion of the coating in the substrate. It will therefore be appreciated that it will be preferable to only partially saturate the target material.

As will be discussed in greater detail below, the preferred embodiment of the invention will also include the ability to generate and transmit a plurality of transmitter flux of differing frequencies, either simultaneously or sequentially. The preferred embodiment will also include the ability to detect and measure receiver signals from a plurality of directions. It may also incorporate a plurality of separate receiver coils. An embodiment may also have the capability to partially saturate one or more portions of the coated metal in order that one or more frequencies of oscillating magnetic flux may be induced in and focused or directed through partially saturated metal or other magnetically permeable and electrically conductive material utilizing the Magnetic Lensing™ focus effect.

An embodiment of the invention may also incorporate one or more means to null direct coupling of magnetic flux signals between the transmitter and receiver, i.e., the direct transmission of the transmitter current to the receiver coil. In addition, an embodiment of the invention will include means to accurately measure changes in coating and substrate properties, e.g., conductivity, permeability and thickness.

It will be appreciated that there may be a plurality of components or subsystems in the invention.

These can include the following:

Full saturation magnetic flux circuit

Partial saturation magnetic flux circuit

Transmitter/receiver system

Nulling system—geometric, electronic, permeability

Automatic lensing system

Conductivity/permeability measurement system

Wall thickness measurement system

All or some of these subsystems may be incorporated into the apparatus subject of this invention. Each will be discussed in greater detail below.

1. Full Saturation Magnetic Flux Circuit

The design of the saturating magnetic flux system (hereinafter “saturation flux generator”) allows the reduction of the permeability of the adjacent portion of the target metal to relative permeability of near unity. It will be appreciated by those skilled in the technology that the material comprising the target metal, e.g., carbon steel, may have a magnetic permeability in excess of 10,000 henry/meter. A fully saturated portion of the metal is, however, transparent to the transmission of additional magnetic flux. In this state of full saturation, the fully saturated or transparent portion of the metal can not absorb further magnetic flux. Therefore, a second and oscillating magnetic flux from the transmitter of the invention will readily penetrate into the transparency created in the metal coating and metal substrate. It is therefore possible to measure the electrical resistivity of the both the coating and the substrate proximate to the transparency generating device subject of the invention.

The depth of penetration of the oscillating magnetic flux into the media within the near field of the saturated metal is proportional to the separation distance between the transmitter and receiver of the invention. This can be useful in some applications. A series of receivers placed at varying distances from a single transmitter could establish various depths of measurement directionally into the metal proportional to these separations. It will be noted, however, the as the separation distance “D” between the transmitter and receiver(s) is increased, the density of the flux decreases at a rate of 1/D³ and that when the target metal is fully saturated, i.e., its relative permeability approaching “unity” or 1, it is not possible to utilize Magnetically Lensed oscillating flux.

2. Partial Saturation Magnetic Flux Circuit

When in a state of partial saturation, the effected portion of the coated metal can be used for the Magnetically Lensing effect or focus of the oscillating flux. Simply stated, when partially saturated, the permeability of the metal is substantially reduced, thereby allowing greater penetration of oscillating transmitter flux into the target material, particularly flux oscillating at relatively high frequencies. However, the relative permeability of the metal is greater than unity. The partially saturated metal continues to absorb a significant portion of the transmitter flux. Since the coated metal is also electrically conductive, the oscillating magnetic flux induces eddy currents within the partially saturated metal. Oscillating magnetic flux induced by the eddy currents is emitted from the metal into one or more receiver coils contained within the apparatus of the invention. The reduced permeability can be utilized to control and concentrate this induced magnetic flux within the metal.

It will also be appreciated that the Magnetic Lensing focus may be utilized with a separate and partially saturated magnetically permeable and electrically conductive material located proximate to the target material. Induced oscillating magnetic flux transmitted from the separate and partially saturated material may directed or focused into the target material. This allows measurement of the properties of metal coating and metal substrate more distant from the apparatus than can be achieved by controlling the separation distance between the transmitter and receiver.

This focusing of magnetic flux can be controlled, allowing the lines of oscillating magnetic flux emitted from the transmitter to be focused on the coated target metal at a greater distance and at lower power. This facilitates inspection over surfaces containing imperfections, such as welding beads. This focusing partially counteracts the normal rapid geometric spreading of magnetic flux. Concentrating the magnetic flux allows distant sensing using much less power.

3. Transmitter/Receiver System

There may be a multiplicity of transmitter/receiver configurations and orientations.

(a) Transmitter—There may be more than one transmitter oriented directionally to the target coated metal. In addition, multiple transmitter signals of the same frequency may be bucked with respect to each other to propagate the transmitter flux further into the target metal. Also this bucking or interaction among magnetic flux oscillating at the same frequency may be used to direct transmitter flux in a controlled manner. A plurality of transmitters may be configured to achieve a desired transmitter signal geometry.

(b) Receiver—There may be a plurality of receivers used in an evenly or unevenly spaced array. Receiver's may be bucked or used to enhance the signal or establish directionality of received signals.

4. Nulling System

The receiver system must be nulled with respect to the transmitter system. This nulling prevents the receiver system from being overwhelmed by the signals emitted from the transmitter system. It also minimizes the interference of extraneous electrical signals, i.e., electrical noise. It has been found that a combination of several nulling techniques provides the best results. These techniques include (a) geometric nulling, (b) electronic nulling, and (c) transmitter signal absorption by permeability.

(a) Geometric nulling—A wide combination of geometric nulling systems may be used. The respective design and location of each transmitter and receiver may vary in consideration of the placement and design of the other transmitters or receivers and in consideration of the location and geometry of the Metallic Transparency region. Therefore, by not wrapping either the transmitter or receiver coils, or both, around the saturation flux generator allows a number of advantages. These are:

1. Mechanical nulling by receiver or transmitter placement or rotation with respect to each other, or with respect to the target metal.

2. Directionality by placing the magnetic saturation core close to the target region of the coated material.

3. Minimizing possible saturation of the Saturation flux generator core that would cause uncontrolled dispersion of saturation flux. The dispersed magnetic saturation flux may achieve only partial saturation of a selected portion of the target material. This may be a desired result. This is exactly opposite the concern cited in U.S. Pat. No. 5,038,107 which does not want to use an ac current on the saturation core that may take the core out of saturation.

4. Since the transmitter coil can have an air core, laminated core or smaller inductor core than the saturation core, much higher frequencies can be used for the transmitter signal. This is due to the inductive impedance resulting from the presence of a large metallic saturation core. This large saturation core drives up the total impedance of the system.

5. Multiple transmitters, each at different frequencies, may broadcast simultaneously to perform spectroscopy over a large frequency range.

6. Modification of the geometry of the transmitter will also cause the geometry of the oscillating magnetic flux field. Therefore varying the design of the transmitter, e.g., varying the coil length, may also be used to control the portion of the target metal that will be investigated.

7. For applications utilizing full saturation of a portion of coated metal, the transmitters and receivers must be placed in sufficient proximity to the Metallic Transparency region to prevent a large amount of either transmitter signal or receiver signal being absorbed into the non-saturated high permeability metal structure being investigated.

8. Multiple transmitters can be used to “buck” each other, thereby causing the geometry of the combined oscillating magnetic flux field to be altered. This may increase the distance that can be achieved between the apparatus and the target without utilization of the Magnetically Lensing focus effect of the transmitter flux.

9. Multiple receivers may be either nulled with respect to each other and/or built into an array for improving signal receiving resolution. These techniques may incorporate reversing the direction of at least one of the transmitter coils or altering the length of at least one of the transmitter coils in relation to the other(s).

(b) Electronic nulling—In this nulling type, it is possible to either null by creating a receiver signal 180° out of phase and exactly in reverse amplitude to the transmitter signal. Another method is measuring the receiver signal attributable to direct transmission of magnetic flux from the transmitter and subtracting this value from the total measured receiver signal.

(c) Permeability nulling—In this nulling method, a variety of materials may be used to absorb the transmitter signal before it reaches the receiver. This may be accomplished by separating the transmitter and receiver by enough high permeability material to absorb the transmitter signal before it reaches the receiver coil. Another absorption method is to isolate the transmitter from the receiver by highly magnetically permeable materials that will absorb or attenuate the oscillating transmitter flux prior to reaching the receiver

5. Automatic Lensing System

One variation of the invention utilizes an oscillating transmitting current penetrating a partially transparent material. This oscillating current induces eddy currents within the electrically conductive material. The eddy currents induced within the material induce a separate oscillating magnetic flux. The field of this oscillating magnetic flux radiates into the proximate targeted coated metal surface. This oscillating magnetic flux will, in turn, generate separate eddy currents within the effected region of the electrically conductive and magnetically permeable coated metal.

In this manner, the partially saturated and electrically conductive material serves as an antenna for the transmission of oscillating magnetic flux. In addition, the Magnetic Antenna TM capability can be utilized to focus or direct the second and separate oscillating magnetic flux in a controlled manner. This feature is termed “Lensing” and is the essence of the “Magnetic Lens™”.

There is a relationship between the amount of power utilized by the saturation flux generator required to achieve partial saturation and the power utilized by the transmitter. This relationship can be used to optimize the Magnetic Lensing effect and the strength of the receiver signal. When the transmitter and receiver are separated in a bistatic configuration, it has been found that optimized signal strength is achieved by increasing the saturation current proximate to the receiver by as much as a factor of four over the power utilized to create the partial transparency proximate to the transmitter. This enhances the transparency of the coated metal proximate to the receiver. This relationship between the magnetic flux for the Receiver and Transmitter can be derived by known methods. This relationship varies as the casing metal thickness varies and as the permeability and conductivity also vary.

6. Conductivity, Permeability Measurement System

To perform accurate measurements of the coating contained on the target material, the electrical conductivity and magnetic permeability properties of the substrate must be known.

(a) The conductivity of the substrate is measured at every new reading by analyzing the frequency spectral response over a sufficient range to record the conductivity measurements achieved at various frequencies of oscillating magnetic flux.

(b) The permeability of the casing exhibits a functional relationship to the strength of the saturating coils. Therefore, at each location the power of saturation flux is varied. The frequency of the flux is maintained constant. The change in casing permeability responsive to changes in the saturation flux density is monitored.

7. Coating Thickness Measurement System

Once the conductivity and permeability of the target material are determined, the thickness, diffusion or other properties of the coating metal substrate can be determined by utilization of basic and known scientific principles and algorithms.

### I. Procedures and Test Results

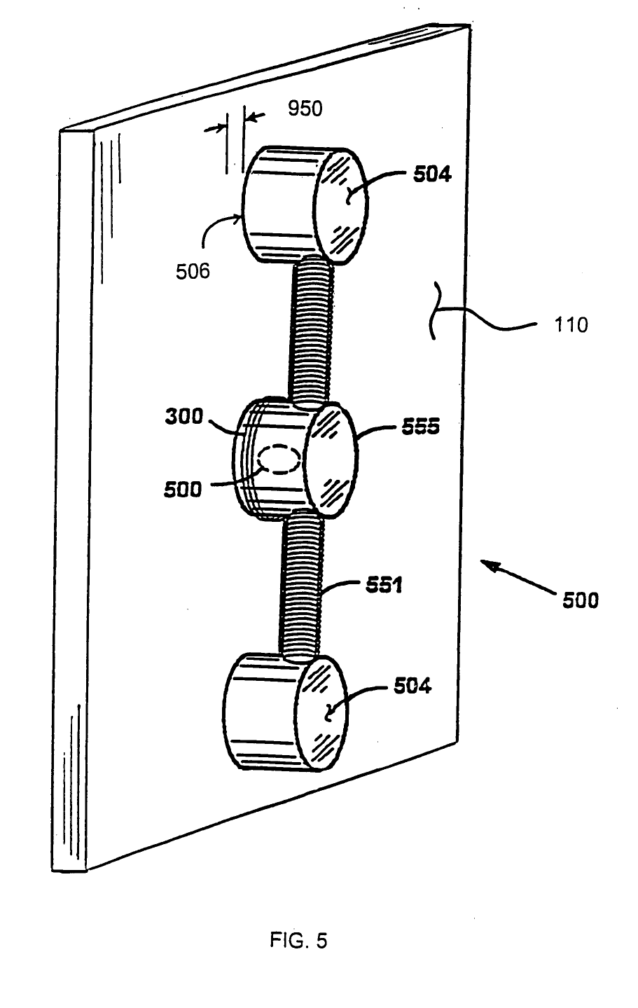

The embodiment of the invention utilized to register the measurements of the chromizing layer is shown in FIG. 5. The apparatus of the invention was mounted on a fixed platform above the samples to be tested. The test samples were placed in a holder and moved under the apparatus to a fixed stop position. The samples could be rotated in the holder so different sides of each sample could be measured. These azimuthal measurements did in fact indicate some thickness variations at 90-degree rotation intervals. The whole test assembly was constructed of wood so metallic interference would be limited around the samples. It will be appreciated that the apparatus can also be configured to allow it to move over the surface of the target material.

In the procedure, the apparatus was positioned about 1 inch 950 above the samples. The sensor could be positioned lower (i.e. closer) but also much higher. It will be appreciated that a geometrically dependent loss of spatial resolution will occur as the distance 950 between the apparatus and the target material is increased.

The testing procedure began with a preliminary set of parametric initial conditions for each of the systems. The dc system power was varied in quarter amp increments to obtain the maximum signals into the ac receiver. The dc power can be minimized where a highly electrically conductive coating material, e.g., chrome, is placed upon a less conductive material such as carbon steel. For a highly electrically conductive material, such a chrome, placed as a coating the less electrically conductive carbon steel substrate, the dc system power could be kept to a minimum. It can be expected that the primary EM effect of varying the thickness of the chrome coating will be in the measured electrical impedance of the combined material. The value of the measured impedance is inversely proportional to thickness of the chrome coating. This can be detected by the minimal phase shift occurring as the impedance is decreased.

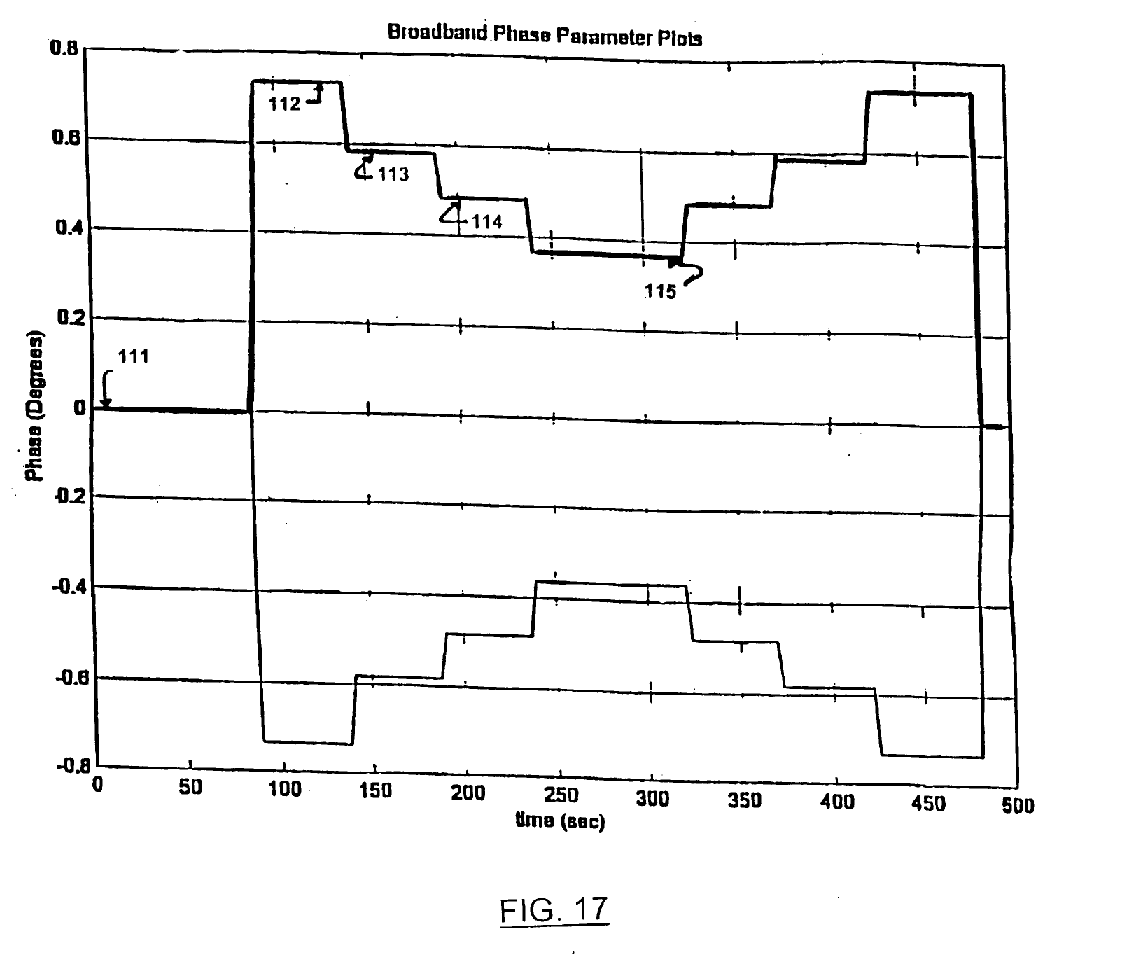

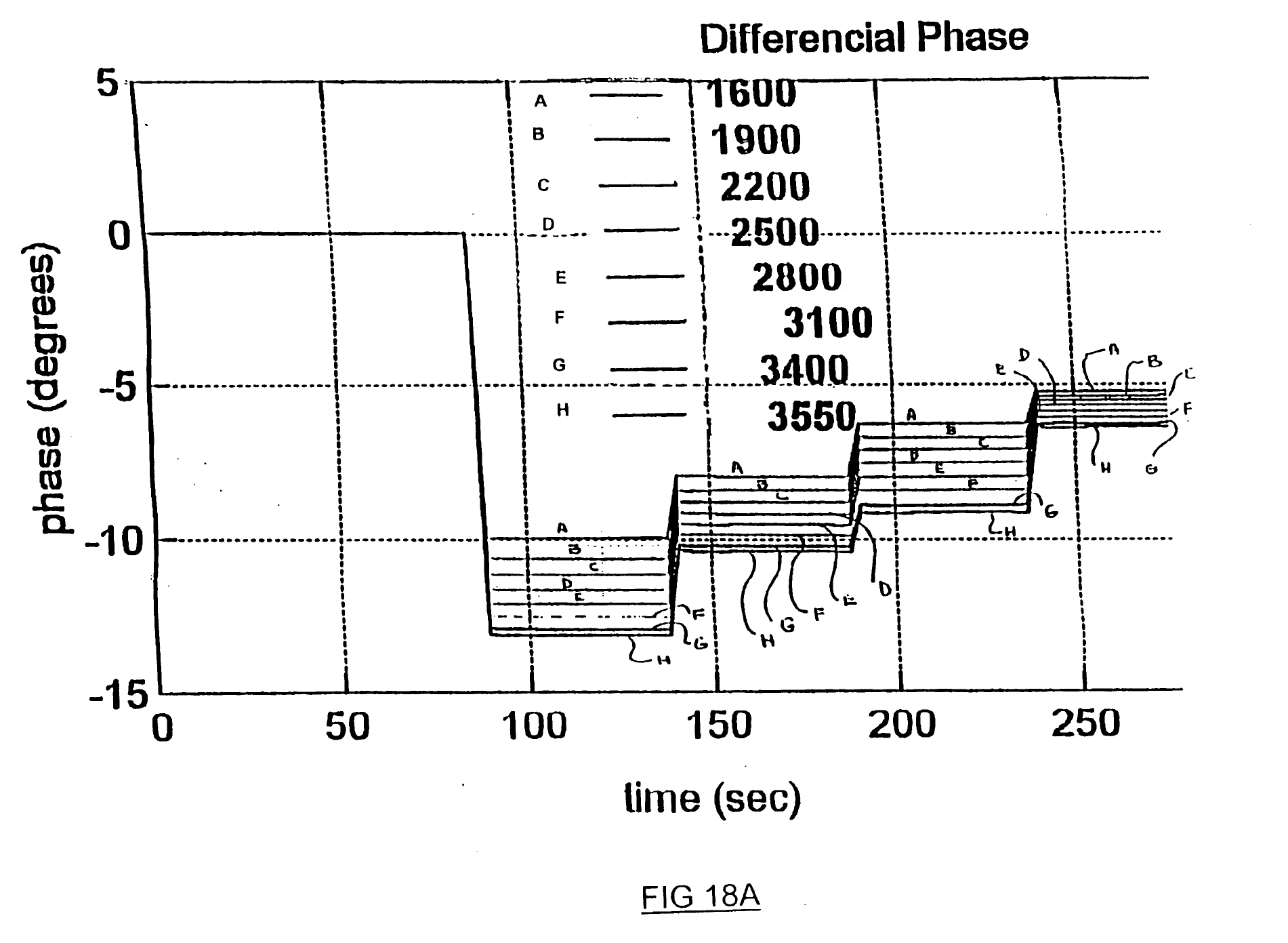

The frequencies of the ac system were chosen by first trying a narrow band of frequencies around two kilohertz. The narrower the band, the more rapid the calculational results. This would in turn, allow the apparatus to more rapidly travel across the target material. However, it was found that a broader band was necessary to overcome anomalies within the coating layer. It was found that large signal losses occurred due to areas containing thinner chrome coatings. The frequency band chosen was therefore between 1.5 and 3.5 kilohertz. The entire range of frequencies was needed to work together. Attempts to obtain measured data using an isolated single frequency or subset of the total range of frequencies did not yield the true results over all the tubing samples. Satisfactory results were obtained using one or more pulsed signals comprising 15 sweeps. Only two pulses at 15 sweeps were necessary to identify a coating thickness. The results are shown in phase graphs of the different coating samples in FIG. 17 and FIG. 18.

FIG. 17 shows the frequency deconvolution of the phase plots. As the chrome thickness increases and the “lossiness” of the substrate decreases, the phase angle is reduced. The software system was initialized with the non-coated tubing. Thereafter, the software showed the samples with the greatest losses or larger phase change to have the largest deviation from zero. As the increased chrome layer reduced the losses, the phase angle was reduced. FIG. 18 shows the summed values of all the frequencies as the test samples are measured from 6 mils to 20 mils then tested in reversed order. The results are repeatable. It will be appreciated that the method and apparatus of this invention can achieve resolution of the coating thickness to fractions of one mil.

By altering the concentration of the saturation flux, the frequency of the transmitter flux, placement of the transmitters and receivers, or by the orientation of the transmitter in relation to the saturation coil, it is possible to vary the depth of penetration into the target material, thus building a detailed characterization profile of the material and the dispersion of the coating within the substrate.

Reference will now be made in detail to the present preferred embodiments of the invention as described in the accompanying drawings.

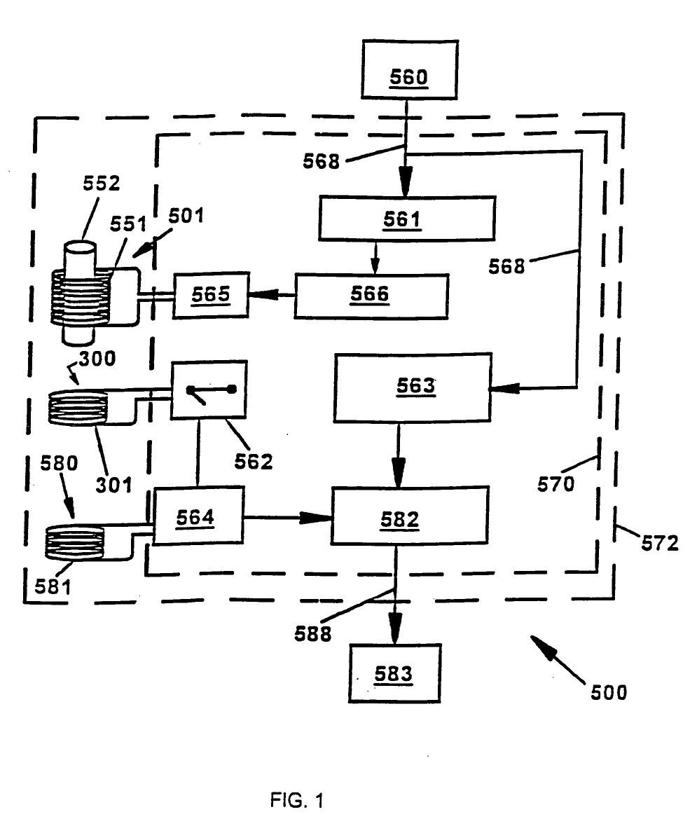

FIG. 1 illustrates schematically one embodiment of the components of the coating thickness measuring apparatus 500 subject of the invention. The components of the apparatus utilized within the immediate proximity to the target metal may be contained within a housing 572. These components may include (a) a saturation flux generator 501 capable of fully or partially saturating the target material (thereby creating a full or partial Metallic Transparency in a magnetically permeable coated material), and comprising a saturation coil 551, (b) a magnetic flux transmitter component 300, comprising the transmitter coil 301, a switch 562, and a low noise amplifier (LNA) 564, (c) a receiver component 580 for the receipt and measurement of oscillating magnetic flux emitted from the target metal and comprising a receiver coil 581, (d) a frequency generator 563, (e) a pulser 566, (f) one or more capacitors 561 and (g) a nulling device 582. The magnetic saturation generator, includes the saturation coil 551, saturation core 552 or, alternatively, magnetic culminator (not shown). The magnetic saturation generator 501, saturation coil 551, the transmitter 300, transmitter coil 301 and any associated core (not shown), the receiver 580, including the receiver coil 581; and the associated components described above and depicted within the tool housing 572, can be maneuvered around and over the target metal. The output display 583, operator controls (not shown) and power source 560 may be located away from the target metal and linked to the tool housing 572 by standard known means. This may include utilization of electronic communication and power transmission cables and connectors 568 and 588. Wireless remote communication devices may be used. The self contained power unit, e.g., a battery, may also be contained with the housing 572. The operator's console or display 583 may also record and display historical trends of resistivity.

The saturation coil 551 and saturation core 552, the transmitter coil 301 and the receiver coil 580, are often depicted separately from the other components described above and depicted within the “electronics component” 570. For clarity, many of the drawings contained within this specification do not depict the electronics component. Further, the drawings may show an illustration of a coil only, but may be variously labeled as a saturation flux generator, transmitter or receiver. It is understood that the other components or sub-components are deemed to be included as necessary. In addition, the components of the invention, including but not limited to the saturation coil, transmitter coil and receiver coil are not placed in physical contact with the targeted and coated metal surface.

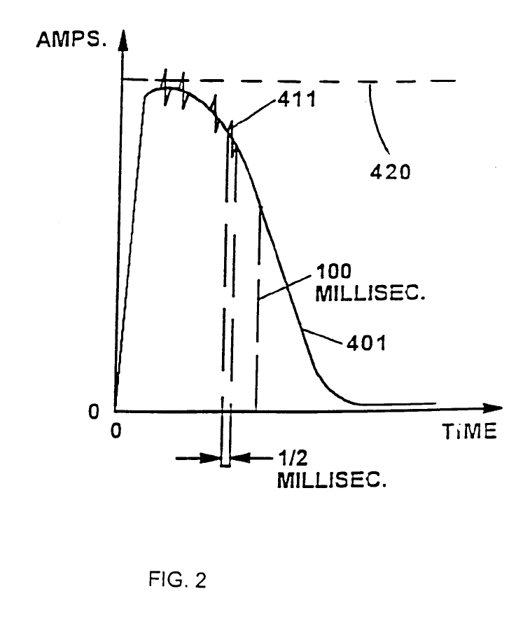

FIG. 2 illustrates a graph of current versus time with respect to the present invention. FIG. 2 illustrates several significant features in practicing the present invention: the level or quantity of saturation flux required to achieve saturation of the target metal 420, the oscillating higher frequency transmitter flux 411 and, as compared with the transmitter flux, the lower frequency of the actual saturation flux 401 or if dc powered, constant amplitude of the saturation flux (not shown). The higher frequency transmitter signal 411 is imposed on the lower frequency saturation flux 401. FIG. 2 illustrates the higher frequency oscillating transmitter signal as spikes 411 disposed along a lower frequency oscillating saturation flux 401. In one embodiment of the present invention, the transmitter signal 411 may be transmitted only during the duration of each cycle of the oscillating saturation flux 401 that is above the level 420 required for saturation. Among other advantages, the latter embodiment minimizes energy consumption. In the latter embodiment, it is possible to have multiple transmissions of transmitter signal 411 during each phase that the saturation flux 401 is above the saturation level 420.

The saturation flux 401 may not achieve the level of current (flux density) necessary to saturate the targeted area of the magnetically permeable material. However, when partially saturated, the target material will allow a significantly greater portion of the distinctively higher frequency transmitter flux 411 to couple, i.e., penetrate, into the material. If the material is electrically conductive, the oscillating magnetic flux will induce electrical eddy currents within the material. In another embodiment, the magnetic saturation flux 401 may be generated from at least one permanent magnet, a low frequency ac current or a direct current dc electromagnetic device.

Illustrated schematically as an apparatus in FIG. 1 and conceptually in FIG. 2, the saturation coil 551 generates the transparency current (saturation flux) which in turn creates a Metallic Transparency region within in the target metal. The saturation coil is comprised of conductive material preferably wrapped around a highly permeable core (saturation core or flux circuit core) and powered either by DC current or a current oscillating at a low frequency. The transmitter signal 411 may be generated by the transmitter 300, comprised of the coil 301 of conductive material, powered by alternating current, preferably at a controlled frequency, wrapped upon or near the saturation coil 551. Preferably, the transmitter signal is at a higher frequency than the transparency current. It is preferred that the frequency of the transmitter signal be at least a multiple of 10 greater than the frequency of the transparency current (also termed saturation flux). As discussed above, the higher frequency of the transmitter signal relative to the transparency current allows, for example, 10 wavelengths of the transmitter signal to be emitted, and thereby penetrate into the target metal for inducing a separate oscillating signal that may be detected and measured by the receiver before the Metallic Transparency region is closed by the transparency flux falling below the level 420 required to achieve saturation.

In FIG. 2, the high frequency transmitter signal 411 is illustrated being pulsed at less than 0.5 millisecond rates. If the lower frequency transparency current 401, generated by the saturation coil 551, is pulsed or activated “on” for 10 milliseconds 430, there is sufficient time for twenty transmitter signals (e.g., with a wavelength of only 0.5 millisecond) to be emitted through the saturated metal or, in other embodiments, through the culminator or saturation core and to the targeted material. As explained in the preceding paragraph, these 20 oscillating signals 411 emitted during the “on” pulse of the transparency current 401 may induce oscillating eddy currents that may be detected and measured by the receiver located within the saturation core and comprising part of the measuring apparatus subject of this invention.

For most applications, a power source of 300 watts or less is sufficient to create the transmitter signal and transparency current. For thicker material, strong pulses and signals may be generated by utilizing the charge storing capacitors 561. The capacitors 561 are slowly charged then quickly discharged through a switch contact and then through the low impedance large coil 551. At the same time, the higher frequency small signal coil 300 is pulsed.

Although the invention may be used with any coated material having electrically conductive or magnetic permeable properties, the foregoing description may refer to metals or metal coatings. The invention is not, however, limited to metals. With reference to the preceding abbreviated outline of the invention and FIG. 1, the invention comprises the following steps and utilizes the referenced components and sub-components: (1) the saturation coil 551, when energized, acts as an electromagnet. The saturation coil creates one or more fields of magnetic flux through the saturation core 552 or culminator 555 adjacent or near the target coated metal (not shown). The saturation coil creates a partial or full magnetic saturation within at least a portion of the coated metal immediately proximate to the saturation coil 551. Saturation results in the magnetic permeability of the metal being substantially lowered. When fully saturated, that portion of the metal cannot absorb further magnetic flux, thereby allowing additional flux to pass through that portion of the metal. In such a state, that portion of the metal becomes a metallically transparent region to magnetic flux. In order to create a fully Metallic Transparency region, the full saturation must extend through the thickness of the coated metal. (2) The transmitter 300 then creates one or more fields of additional magnetic flux having frequencies preferably equal to or greater than the saturation flux. The second field of magnetic flux is engaged with the section of full or partial saturation (having greatly reduced magnetic permeability) allowing the transmitter flux to pass through the transparency of the metal. Through basic electromotive forces, a separate oscillating magnetic flux is induced in the electrically conductive material. (3) The induced magnetic flux travels back to the receiver 580 contained within the apparatus 500 of the invention. As in step No. 1 above, the same or similar saturation coils 551 create a fully or partially saturated area within the target metal near the receiver 580 so that the induced magnetic flux can be detected and measured through the Casing. (5) The receiver converts the induced flux into electronic signals that are filtered and processed in order to determine the resistivity of coated metal within the target area. The received signal is processed using various electronic components (which may be located within the electronic component 570) to concentrate and magnify the reacted oscillating magnetic signal. The invention may contain means 582 to electronically null the transmitter flux to minimize direct transmission of flux from the transmitter 300 to the receiver 580 and to minimize the interference of electronic noise. The transmitted signal is compared to the received signal and, using the changes in amplitude and phase, the resistivity is determined and displayed. These signals are then sent to the Output Display 583 for further processing, display, and recording.

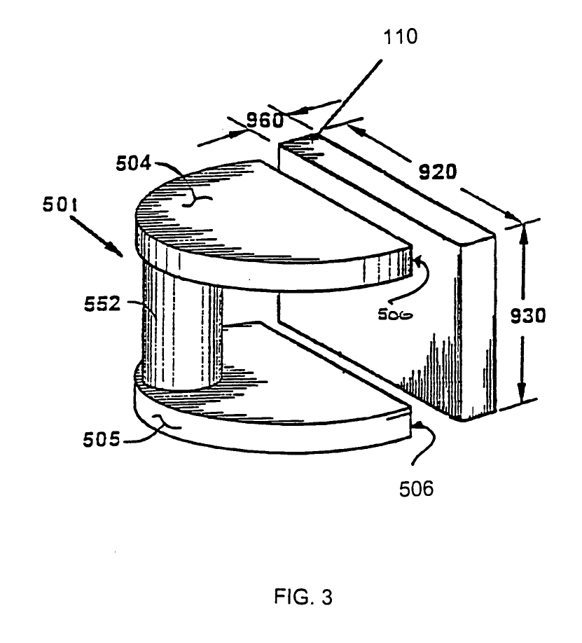

FIG. 3 illustrates a saturation core comprised of electrically conductive and magnetically permeable material. The saturation coil is wrapped around the core 552 and the magnetic flux is directed along the core and into the sub-component flanges 504 and 505. These sub-components at as separate magnetic poles for the electro magnet created when the saturation coil is energized.

It will be appreciated that multiple cores 552, each containing separate saturation coils, may be configured to merge into a single flange. In order to maintain the desired directional control of this sub-component, it is essential that the combined flux not saturate this material. Accordingly, it is preferred that this component must be selected of a highly magnetically permeable material with sufficient mass. When acting as the single pole to separate electro magnets formed by multiple saturation cores, this component 504 in FIG. 3, is termed a culminator. FIG. 3A illustrates a culminator 555 and the multiple separate saturation cores 551.

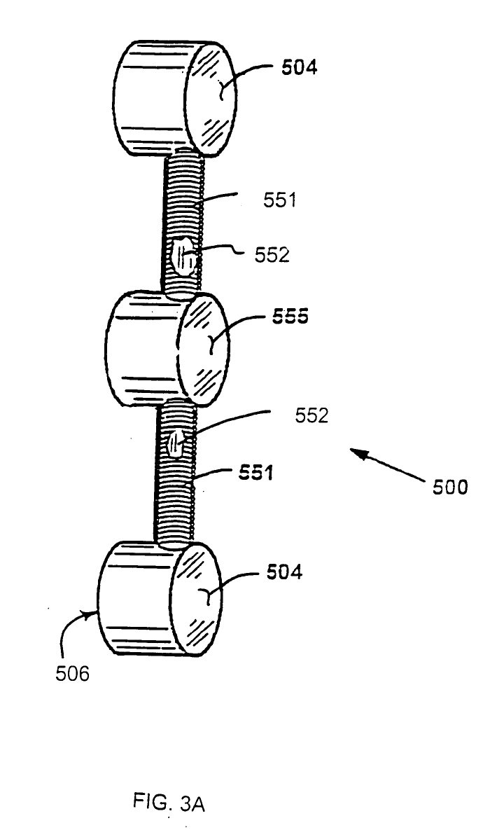

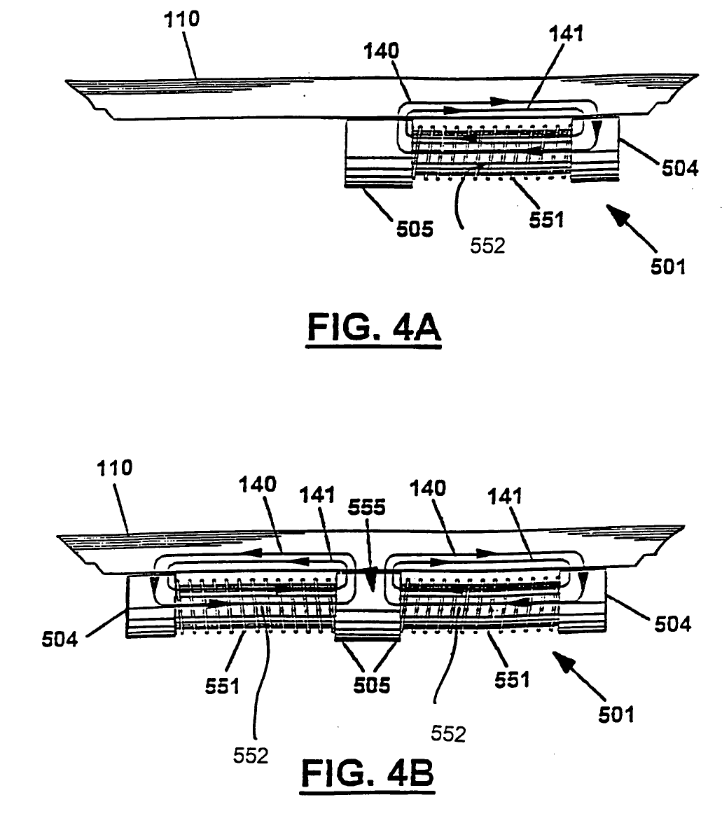

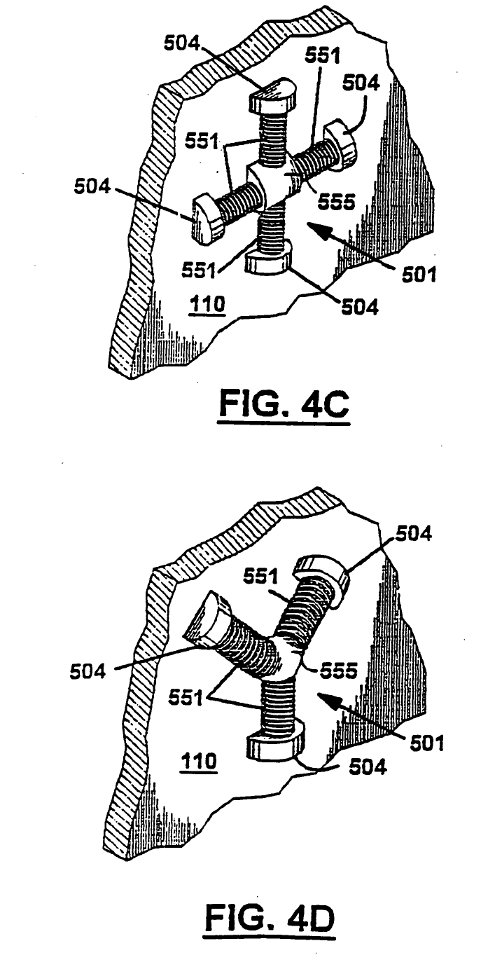

FIGS. 4A and 4B illustrates a saturation flux generator 501 containing the saturation coil 551 wrapped on the core 552, separate magnetic poles 504 and 505 and magnetic flux lines 140 and 141 engaged with the target metal 110. It will be appreciated that the saturation flux generator 501 does not physically contact the surface of the target metal.

FIG. 4B illustrates two separate saturation coils 551 joined at a single sub-component 555. This sub-component contains two like magnetic poles 505 for the two electromagnets formed by the energized saturation coils. This sub-component is termed a culminator 551 and is comprised of an electrically conductive and highly magnetically permeable material with sufficient mass that it does not become saturated by the flux of the electromagnets. As discussed further, it will also be appreciated that it not become saturated with the combined oscillating magnetic flux of any transmitter or receiver.

FIGS. 4C and 4D illustrate other configurations of saturation flux generators 501 incorporating multiple saturation cores 551 and a single culminators 555 concentrating and directing the saturation flux to facilitate coupling with the target metal.

FIG. 5 illustrates a preferred embodiment of the invention wherein the culminator 555 contains the receiver 580 nested inside the transmitter 300. Accurate measurements with minimal energy consumption have been obtained by nesting the nulled receiver inside the transmitter coil 300. This configuration, i.e., a single saturation flux generator 501 containing both the transmitter and receiver, is termed a monstatic configuration. The illustrated saturation flux generator is configured to create a single Transparency in the target metal 110. The saturation coil 551, transmitter 300 and receiver 580 are each nulled 90° to the other.

In FIG. 5, the area of the target metal (not shown) wall thickness measurement is a function of the transmitter coil 300 diameter. Note that the transmitter coil is wrapped on the exterior of the culminator 555, thereby creating a relationship between the culminator, and the energy utilized to transmitted saturation flux into the target metal, and the size of the transmitter coil diameter 300 and thickness of the target metal (not shown) that can be permeated and measured. For the above reasons, FIG. 5 illustrates a preferred embodiment of the invention, allowing compact size, decreased mass and energy consumption, and enhanced accuracy.

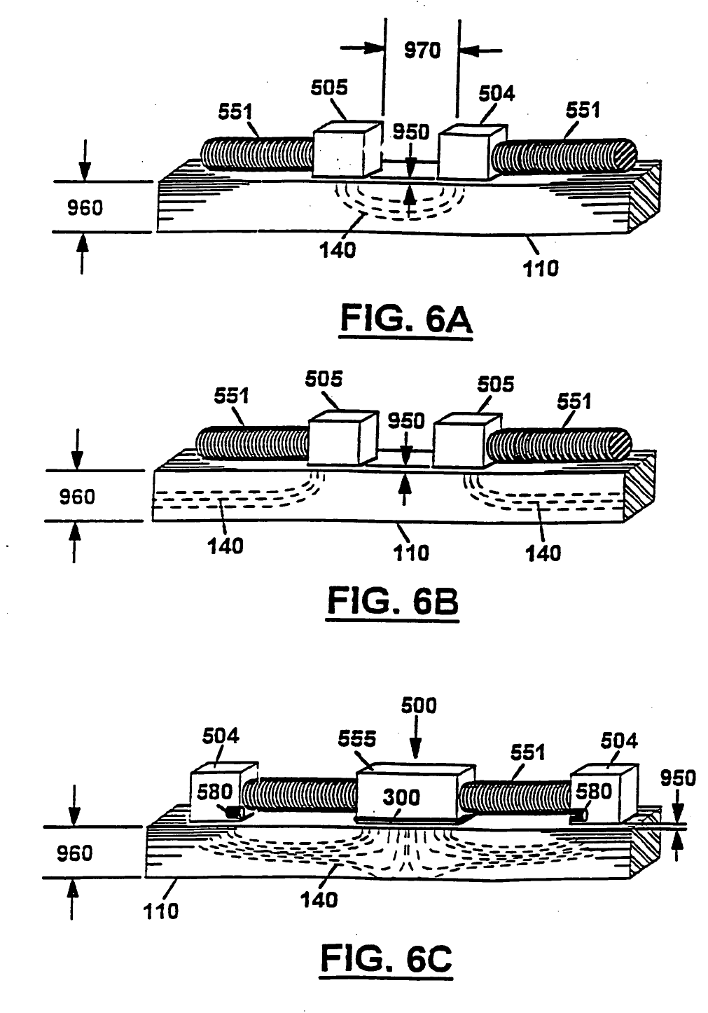

FIGS. 6A, 6B and 6C show alternate saturation flux generators. FIG. 6A illustrates the flux field 140 engaged in the target metal 110 by two unlike poles 504 and 505. FIG. 6B illustrates the magnetic flux field 140 engaged in the target metal proximate to two like magnetic poles 505 and 505. It will be appreciated that the depth of penetration into the target metal, having a thickness 960, will be a function of the separation between the magnetic poles 970.

FIG. 6C illustrates the flux field 140 achieved by the use of the culminator 555. It is important to note that the proximity of the like magnetic poles 505, literally contained within the single mass of the culiminator 555, causes the bulge or bucking of the flux lines into the target metal 110, thereby facililtating coupling of the flux field 140 through the entire thickness of the target metal with minimized size of the sub-component and power.

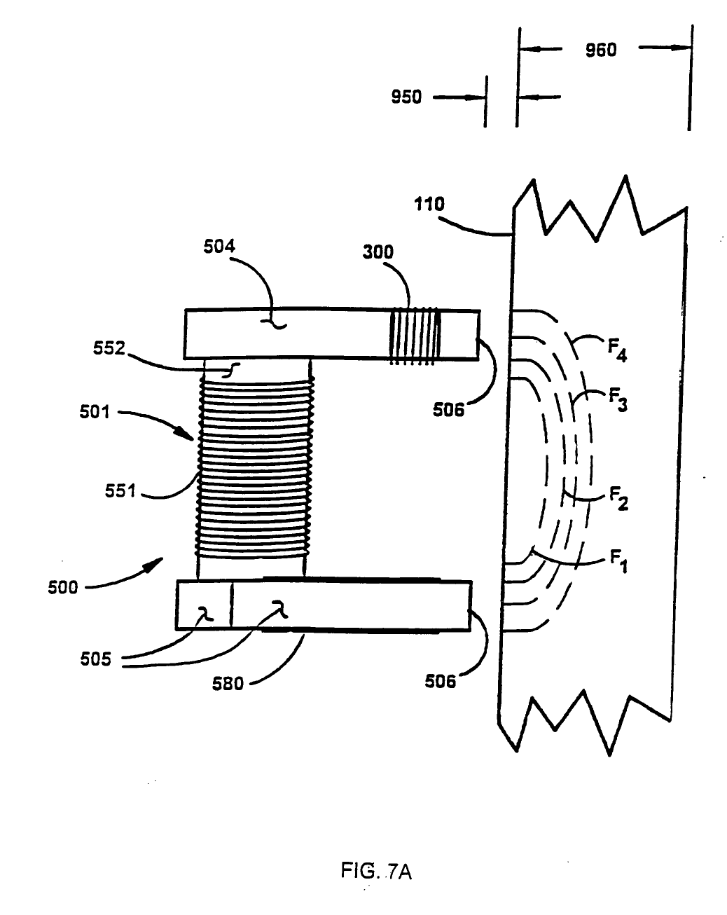

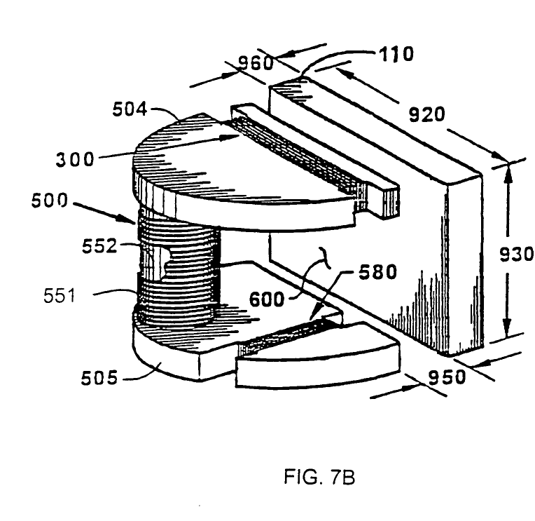

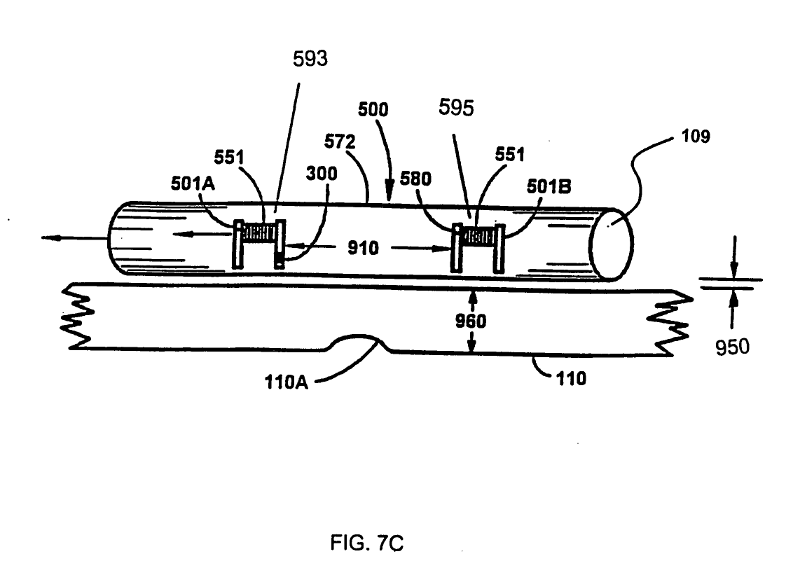

FIG. 7A illustrates a saturation flux generator similar to that illustrated in FIG. 3, but now showing the saturation coil 501 wrapped on the saturation core 552, the transmitter 300 wrapped on flange 504 and the receiver 580 wrapped on flange 505. Note that the saturation coil, transmitter coil and receiver coil are all oriented 90° to the other. The saturation flux lines F1 through F4 are illustrated engaged with the target metal 110 having a thickness 960. The gap 950 between the tool 500 prevents an electric current between the tool and the metal.

FIG. 7B illustrates a magnetic culminator 555 that incorporates a transmitter 300 and a receiver 580. In the preferred embodiment, the axis of the transmitter coil 300 is orthogonal to the axis of the receiver coil 580 and that both are orthogonal to the axis of the saturation coil 551A and 551B.

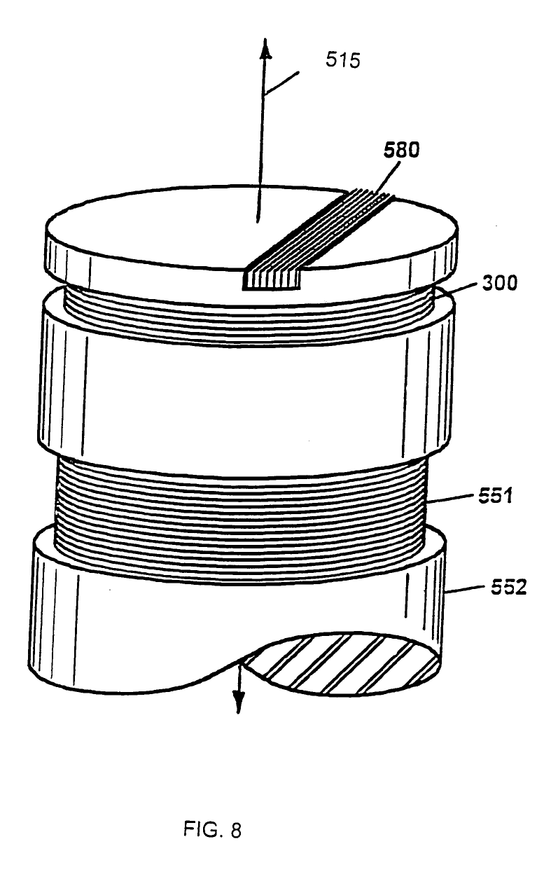

FIG. 8 illustrates an embodiment of the invention wherein the saturation coil 551 and the transmitter coil 300 are separately wrapped around the same saturation core 552. The saturation core is a simple cylindrical shape with both the saturation coil 551 and the transmitter coil wrapped in parallel around the axis of the saturation core 515. Since the transparency coil 551 and transmitter coil 300 have the same diameter, they will have the same magnetic moment (amp turns/meter) arms. This enhances the efficiency of the apparatus since the percentage of transmitter flux engaging with and permeating into the antenna is enhanced.

For the reasons stated previously, it will be appreciated that the saturation flux can not be allowed to saturate the saturation core 552. Further, the transmitter flux will generate eddy currents in the saturation core. Further it will be appreciated by persons skilled in the art that the greatest saturation will occur along the circumference of the saturation core in as much as the permeability of the near saturated or partially saturated saturation core will be lowest at the circumference, i.e., edge of the cylinder. Since the permeability of the electrically conductive and magnetically permeable material comprising the core will approach the permeability of air, the angle of refraction of the magnetic flux (not shown) induced by the eddy current within the saturation core 552 will increase from the perpendicular. It will be further appreciated that this configuration may provide Magnetic Lensing capacity within the saturation flux generator (not shown). This configuration also is a preferred embodiment due to its compact size, energy efficiency, accuracy of measurement and ability to utilize Magnetic Lensing capacity. FIG. 8 also illustrates the placement of a receiver coil 580 nulled to the separate transmitter coil 300.

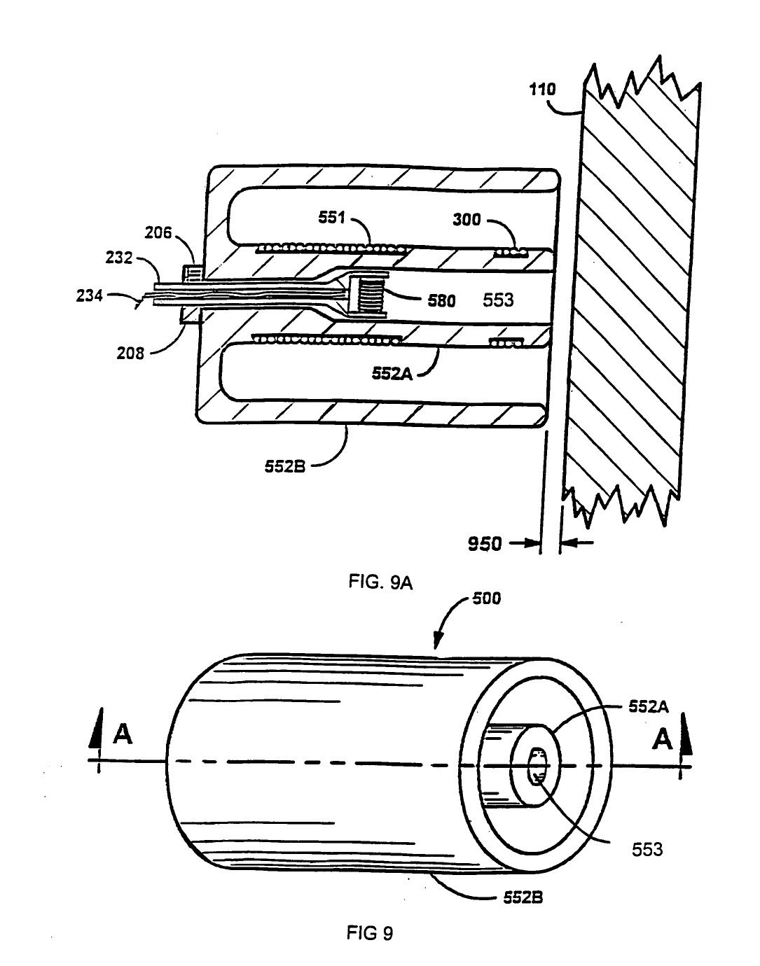

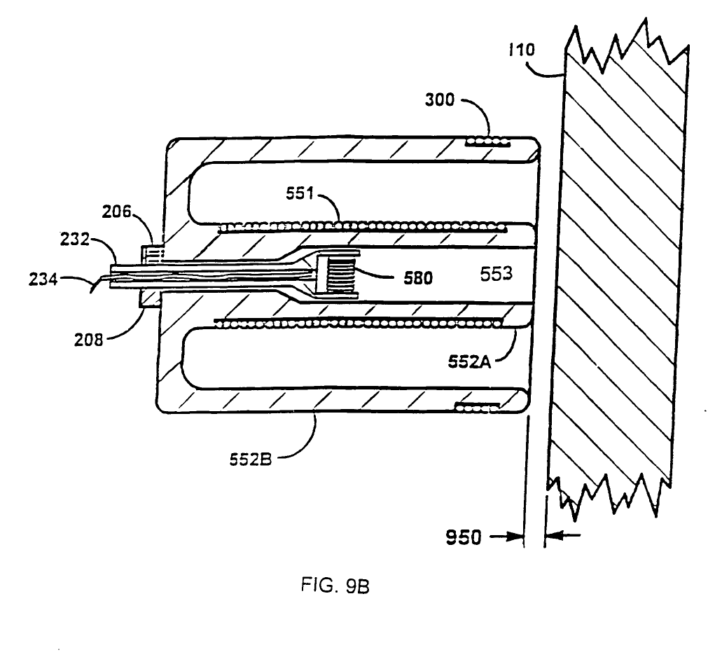

FIG. 9 illustrates the embodiment of a saturation core 552A and 552B, similar the in design to the culminator utilized as a the test apparatus of the present invention. The important commonality is the nesting of the receiver coil 580 within the transmitter coil 300 and that the position of the receiver coil may be adjusted relaltive to the target metal 110 and the transmitter coil 300. In the present invention, the culminator conducting the saturation flux of a plurality of saturation cores also contained the transmitter coil 300 wrapped around the periphery of the culminator and the receiver coil, wrapped 90° orthogonal to the transmitter coil axis (not shown), positioned inside the culminator and moveable along the axis of the transmitter coil, thereby also changing its distance from the surface of the target metal.

FIG. 9 illustrates the saturation coil used in conjunction with a single saturation flux generator to create a Metallic Transparency region within a target metal 110. The saturation core comprises an outer cylindrical portion 552B and an inner cylindrical portion 552A. The transmitter, receiver and saturation coils are disposed on, in or around the outer cylindrical portion 552B and the inner cylindrical portion 552A.

FIG. 9A illustrates an embodiment of apparatus subject of the invention utilizing a saturation core could be adapted in FIG. 9. A transmitter coil 300 is wrapped upon the outside diameter of core 552B at the remote end, (closest to the target metal). A saturation coil 551 is also wrapped on the outside diameter of this inner cylindrical saturation core 552A but at a location more distant from the target metal. A receiver coil 580 is disposed within the inside diameter of the inner cylindrical portion 552A of the core. The receiver coil 580 can be located at different positions using a shaft 232 which telescopes within the inside diameter of the inner cylindrical portion 552A of the saturation core. The telescoping shaft 232 can also rotate using a set-screw adjustment 206 and a set screw housing 208. Also, wiring 234 can be channeled through the shaft 232.

FIG. 9B illustrates another embodiment of tool 500 used for practicing the present invention as could be adapted in FIG. 9. A transmitter coil 300 is wrapped proximate to the end of the outside diameter of the outer cylindrical of the saturation core 552B. A saturation coil 551 is disposed along the outside diameter of the inner cylindrical portion 552A of the saturation core. A receiver coil 580 is disposed within the inside diameter of the inner cylindrical portion 552A of the saturation core. The receiver coil 580 can be located at different positions using a shaft 232 which telescopes within the inside diameter of the inner cylindrical portion 204. The telescoping shaft 232 can also rotate using a set-screw adjustment 206 and a set screw housing 208. Also, wiring 234 can be channeled through the shaft 232.

To eliminate the effects of a varying metallic permeability, it is necessary to create a local Metallic Transparency with the permeability as close to unity as possible while the frequency of the transmitter flux is being varied. Then, while the frequency of the transmitter flux is held constant, changing the amount (amplitude) of the saturation flux will vary the permeability of the coated material.

In regard to the Conductivity/permeability Measuring System of the present invention, it is possible to greatly improve existing methods of measuring the thickness and other properties of the coating by measuring the electrical conductivity of the coated metal through the thickness of the metal. This can be achieved by using a spectrum of oscillating magnetic flux frequencies rather than one frequency. In addition, the metallic permeability must be measured to accurately depict the effects of the target metal upon the measurement of conductivity. Using a range of frequencies allows a single device to function where the coating and metal substrate thickness may vary from zero (no metal) to multiple inches thick. Using a single frequency over a wide range of material thickness causes a significant and undesired loss of resolution and accuracy. Therefore, for a given range of material thickness, a particular group of frequencies will provide improved resolution and better accuracy.

One embodiment of the present invention, as broadly described herein, is a method for creating a spectral EM frequency metallic thickness measurement using Metallic Transparencies. In order to calculate the thickness of a coating or the combined coating and substrate with unknown permeability and conductivity, empirical testing is used to first approximate the conductivity and permeability. Conductivity and permeability can be approximated in any order using techniques herein discussed.

As the frequency increases, the conductive losses increase until the skin depth becomes much less than the thickness of the metal. As used herein, “skin depth” is proportional to the inverse of the square root of the product of permeability, conductivity and frequency.

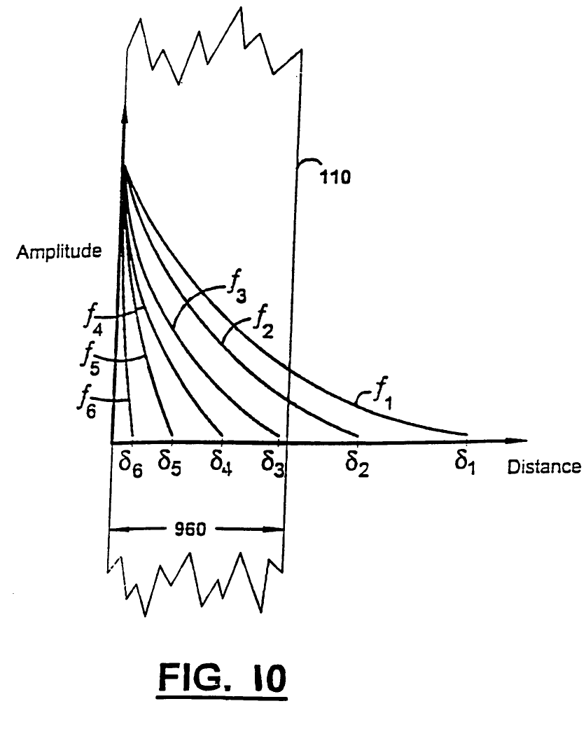

FIG. 10 illustrates the relationship between signal frequency and penetration depth for a cross-section of a piece of metal with a conductivity, a permeability and several imposed frequencies fₓ, for the present invention. For a wave of constant amplitude and varying frequency, and a metal with the same permeability and conductivity, it is known by skin depth theory that a lower frequency penetrates deeper than a higher frequency. Therefore, one can find an optimum frequency range that can characterize the metal conductivity. The relationship of skin depth, permeability, conductivity and the frequency of the oscillating flux can be expressed as:

$$δ = \frac{1}{\sqrt{{σμ}_{r} {μ}_{o} f}}$$

where

δ=penetration depth,

f=frequency,

σ=conductivity

μᵣ=relative permeability, and

μₒ=absolute permeability.

In FIG. 10, the relationship of frequencies is

f₆>f₅>f₄>f₃>f₂>f₁.

The first step to calculate the thickness of the coating metal is to determine the thickness of the metal substrate. This is accomplished by generating a magnetic flux adjacent to or near the metal to be measured. The magnetic flux must be of sufficient magnitude to saturate the metal. The saturation flux may be generated by a permanent magnet, an electromagnet powered by dc current or ac current. The ac generated magnetic flux will preferably be of a relatively low frequency. Upon achieving saturation of a portion of the metal, a second oscillating magnetic flux is generated with specific constant amplitude and engaged with the saturated metal. The resulting magnetic signal from the metal is monitored using a receiver. The receiver is located adjacent to or near the metal to be measured. The receiver may be either co-located with the transmitter or at a distance away, e.g., as in a bistatic configuration. The frequency of the oscillating magnetic flux generated by the transmitter is increased incrementally while the amplitude is held constant and the received signal is monitored.

As required by skin depth theory, for a given wave of constant amplitude and varying frequency, the lower frequencies penetrate deeper into a piece of metal than the higher frequencies. The higher the frequency, the greater loss of signal, i.e., increased attenuation. See FIG. 10. Therefore, an oscillating magnetic flux of a specified frequency can be generated and engaged with the targeted and saturated coated. The received signal is monitored. The frequency of the transmitted flux is increased in a stepped fashion while continuing to monitor the received signal. The amplitude of the transmitted signal remains constant. As the frequency of the transmitted signal is incrementally increased, for example by stepping, the received signal will attenuate. With the amplitude held constant, the maximum frequency of the transmitter signal capable of penetrating the metal is therefor determined when the receiver is no longer able to detect a signal. The last frequency to generate a received signal is the “maximum penetration frequency.” The maximum penetration frequency is used in the present invention to determine material thickness.

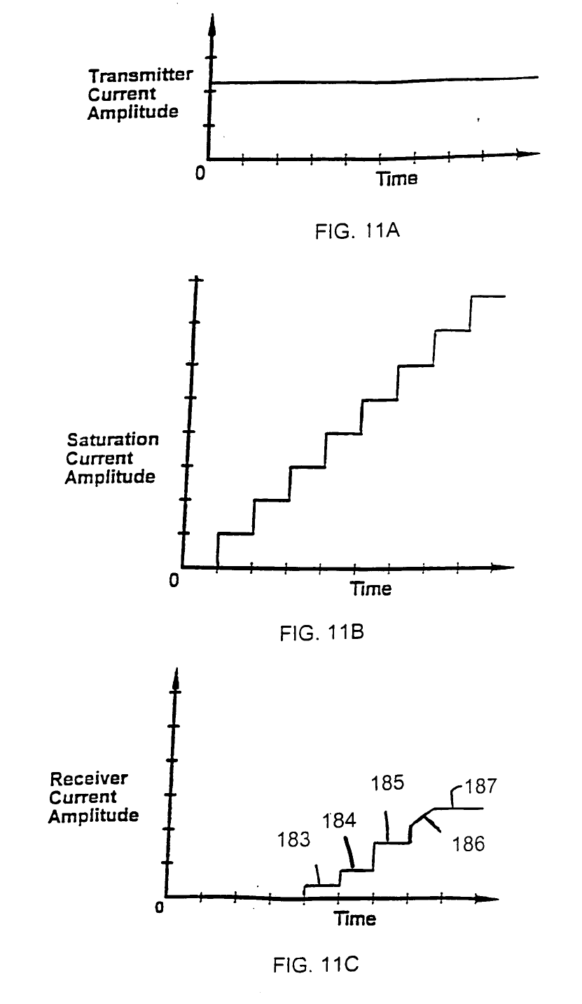

The second step in calculating the thickness of a material with unknown permeability and conductivity is the approximation of permeability. Using the same transmitter, receiver, and saturation procedures described in the first step, a saturation flux is generated near or close to the targeted coated metal. The saturation flux has a known yet variable current. A transmitter flux of known and constant frequency and amplitude is generated at or near the target metal within a zone to be effected by the saturation flux. A receiver monitors the receiver signal from the transmitted signal returning for generating a resulting electromagnetic response. While monitoring the received response and holding the transmitter flux frequency and amplitude constant, the saturation current is increased incrementally. Thus, the receiver signal will generally mirror the steps of the saturation flux but at different amplitudes than the transmitter flux. (See FIGS. 11B and 11C.) As the saturation flux increases, the metal becomes more and more transparent to the transmitter flux (maintained at constant amplitude and frequency), thus, causing the amplitude of the receiver signal to increase proportional to the stepped increases in the saturation flux. The stepped incremental saturation is continued while the transmitter flux is held at the constant amplitude and frequency and the resulting increments in the receiver signal are monitored. This is continued until no further changes are registered by the receiver in response to increases in the saturation flux. The point at which the received signal registers no change may be called “total saturation.” See FIG. 11C. Once total saturation is achieved, increases in the current or amplitude of the saturation flux have no effect upon the received signal. Thus, the transmitter flux is coupled with the coated metal. As the metal becomes more saturated, (and its permeability approaches 1) the metal becomes increasingly transparent, resulting in more of the transmitter flux penetrating though the metal. The current history and the associated received signal, as illustrated in FIGS. 11A, 11B and 11C, provide for full or partial saturation of a localized area. Further, the current history and the received signal information can be used to mathematically determine the permeability and thickness. Once approximation is obtained on either permeability or conductivity, the other variable can be determined and the material thickness can then be calculated.

The technique of the present invention for calculating the thickness of a material with unknown permeability and conductivity can be used to further classify various materials (and the thickness of such materials) such that a general lookup table can be created. The general lookup table can contain known results from numerous test samples allowing for quick lookup and display of thickness based on known samples meeting the test criteria. The test criteria can be for a range of thickness for specified materials having the same permeability and conductivity.

It order to obtain an accurate measurement of permeability and/or conductivity, electronic and geometric nulling are required. Geometric nulling positions the transmitter, receiver and saturation coils in the optimum locations for the particular system designed. Various designs are provided yielding excellent results. Also, an electronic nulling circuit can simultaneously null all of the frequencies at once. Pursuant to practicing the present invention as described herein, one skilled in the art will know and appreciate how to arrange the transmitter, receiver and saturation coils in optimum locations for the particular system being used, and will know and appreciate how to simultaneously null all of the frequencies at once to provide electronic nulling.

FIGS. 7A and 7B illustrate one embodiment of a saturation flux generator 501 used to generate the saturation flux required to practice the present invention. The saturation flux generator 501 is utilized to completely saturate the volume 600 of the target material 110.

In FIG. 7C, the bistatic tool 500 consists of two separate saturation flux generators 593 and 595 contained within a housing 109. The saturation flux generator 593 incorporates a receiver with a receiver coil 581 wound orthogonal to the saturation coil 551. The saturation flux generator 595 incorporates a transmitter 300 with the transmitter coil 301 wound parallel to the saturation coil. The distance between the receiver coil 581 and the transmitter coil 301 is the distance “D” 910. The tool 500 is in operative association with a metal 110 having a defect 599A. It can be appreciated by those skilled in the art that in the bistatic configuration illustrated in FIG. 7C, the distance D must be sufficiently small relative to the geometric size of the defect 599A in order that the tool may detect the defect. Accordingly, the accuracy of the casing thickness calculation is limited by the mass to be evaluated and the displacement distance “D” 910.

The limitation of the displacement distance can be essentially eliminated by a utilization of a single saturation flux generator as illustrated in FIG. 5 and FIGS. 7A and 7B in operative association with a magnetic culminator 555. The transmitter 300 and the receiver 580 are both on the same culminator 555. The displacement distance D between the transmitter 300 and the receiver 580 is essentially zero because of the close configuration of the transmitter and receiver. In the illustrated configurations the receiver and transmitter are geometrically nulled. The configuration illustrated by FIG. 5 has the additional advantage of adaptation to the adjustable nested configuration of FIGS. 9A and 9B wherein the saturation core is replaced with a magnetic culminator. The intensity of the frequencies received will show the metal thickness. For example, if all the higher frequencies are attenuated, the metal is thick. If all the high frequencies are detected with little attenuation of the low frequencies, the metal is thin. For a given power, the displacement distance D between the transmitter 300 and the receiver 580 determines the resolution of the thickness measurement. The resolution effects the size of the defect measurable.

Also, FIGS. 5, 7A, and 7B illustrate alternate embodiments of the saturation flux generator 501 for use with the present invention. The saturation flux generator illustrated in FIG. 7A comprises flux circuit core 552 upon which the saturation coil 551 is wound, two like magnetic poles 504 between which is a magnetic culminator 555. The core 552, upon which the saturation coils 551 of the electromagnet are wrapped, is located between each pole 504 and the culminator 555. Preferably, the saturation flux generator is contained within a housing (not shown) and connected to the power source and instrumentation by conventional means, (also not shown). It will be noted and appreciated by persons skilled in the technology that the saturation flux generator 501 is not in contact with the target material 110.

The complete saturation flux generator 501 incorporates the saturation core 501 for providing a Metallic Transparency that is illustrated having a width W 920, a height H 930 and a thickness L 960. The transparency may be termed the target area. It will be appreciated that FIGS. 5, 7A and 7B illustrate an embodiment wherein the transmitter coils 300, the receiver coils 580 and the transparency coils 551 of the saturation flux generator 500 are nulled to each other.

FIG. 7A illustrates one embodiment of the apparatus 501 of the present invention. The apparatus comprises the saturation coil 551, the transmitter coil 300, receiver coil 580 and the targeted coated metal 110. The saturation flux generator 501 is disposed from the metal 110 by a gap G 150. The metal 110 has a thickness L 160. The tool 500 operates by energizing the saturation coil 551 for saturating the coated metal 110, transmitting a transmitter signal from the transmitter coil 300, and receiving a response via the receiver coil 580. The relative penetration is caused by the change in the saturation current. Thus, as the saturation current increases from i₁, to i_{2, to i}₃, to i₄ then the penetration depth increases from δ₁, to δ₂, to δ₃, to δ₄, respectively. FIG. 7A illustrates the incremental increase in penetration by the field lines F₁, F₂, F₃ and F₄. Also, consideration of the cross-sectional area of each component of the apparatus 501 is required to assure that no component goes into total saturation for a specific power requirement necessary to drive the magnetic flux across the gap G 950.

Using the monostatic saturation flux generator 501 shown in FIG. 7A, the permeability of the target metal 110 may be driven to near unity (total saturation) or to reduced permeability but remaining greater than unity (partial saturation). Oscillating transmitter flux of differing frequencies are transmitted by the transmitter 300 and related induced magnetic flux signals are monitored with the receiver 580. A metallic transparency is created by the saturation flux of the saturation flux generator in a portion of the coated metal 110. An oscillating transmitter signal is generated using the transmitter 300 at a preset frequency and constant amplitude. Assuming the first frequency is within the detectable frequency range, the frequency is increased incrementally until the received signal is lost. The last frequency detected prior to losing the received signal determines the maximum penetration frequency detectable in a certain piece of targeted metal 110 of constant thickness, permeability, and conductivity. Using the data and information received in empirical testing for permeability, the material properties and thickness can be very precisely calculated.

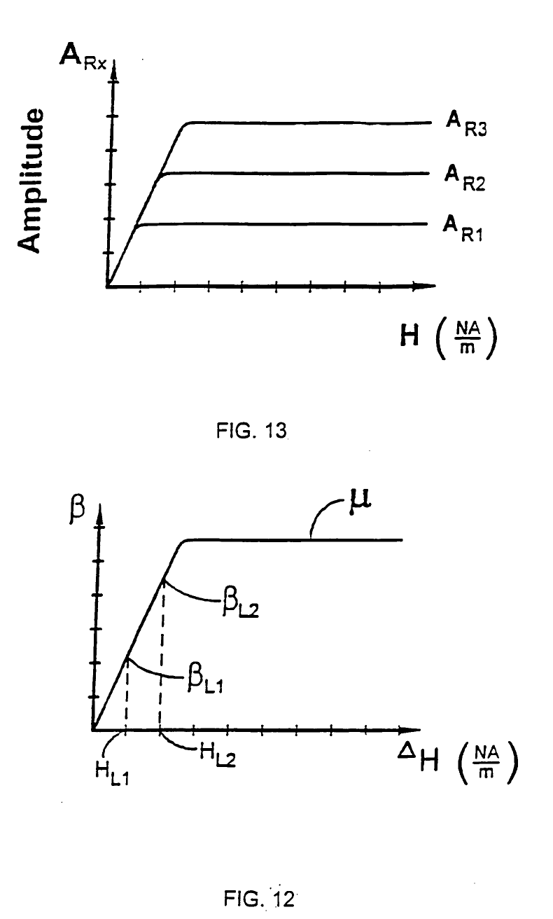

FIG. 12 illustrates the relationship between the flux field β and the change in H (ΔH) in amp-turns/meter. The permeability μ is plotted. For the relationship between the flux field β and ΔH, the function defining the permeability μ remains the same. Although the function defining the permeability μ remains the same, the value of ΔH for thinner materials moves up the curve faster. Thus, incremental changes in H create a faster advancement up the permeability curve toward saturation. For example, a given H_{L1} corresponds to the value of β_{L1} and a corresponding H_{L2} corresponds to the value of β_{L2}. Thus, the value for L2 moves faster up the permeability μ curve than the value for L1.

FIG. 13 illustrates the relationship between the amplitude A_{Rx} of the Receiver Signal and H in amp-turns/meter. As in FIG. 12, the slope of the curve in FIG. 13 is related to the permeability μ. However, the receiver amplitude A_{Rx} reaches a different maximum value depending on the thickness of the metal. For thinner metal, as with other materials, the receiver amplitude A_{Rx} reaches its maximum value at a lower amplitude A_{Rx}. For thicker materials, the receiver amplitude A_{Rx} reaches its maximum value at a higher amplitude A_{Rx}. FIG. 13 illustrates a thinner material having a maximum at A_{R1}, a thicker material having a maximum at A_{R3}, and an intermediate thickness material having a maximum at A_{R2}.

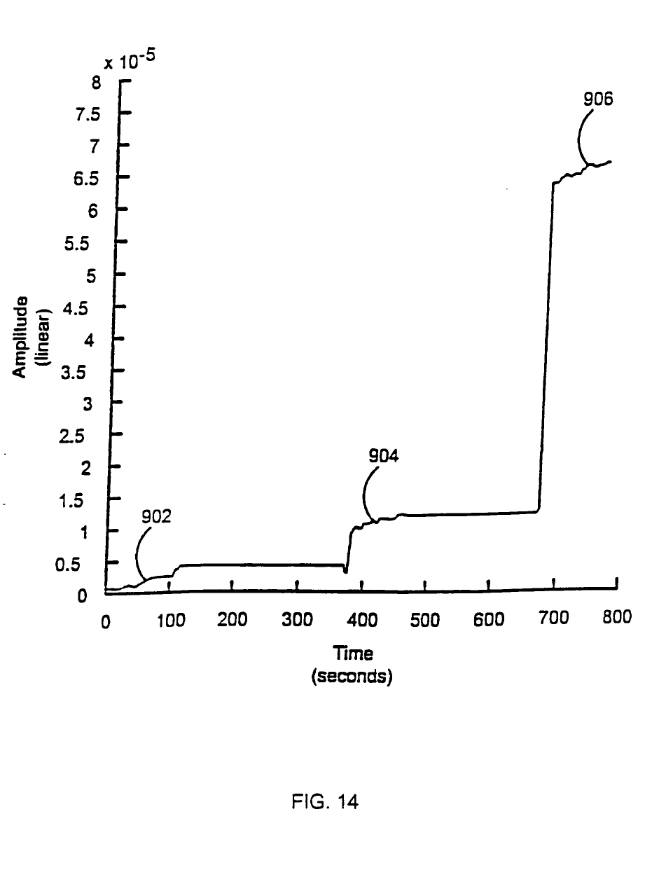

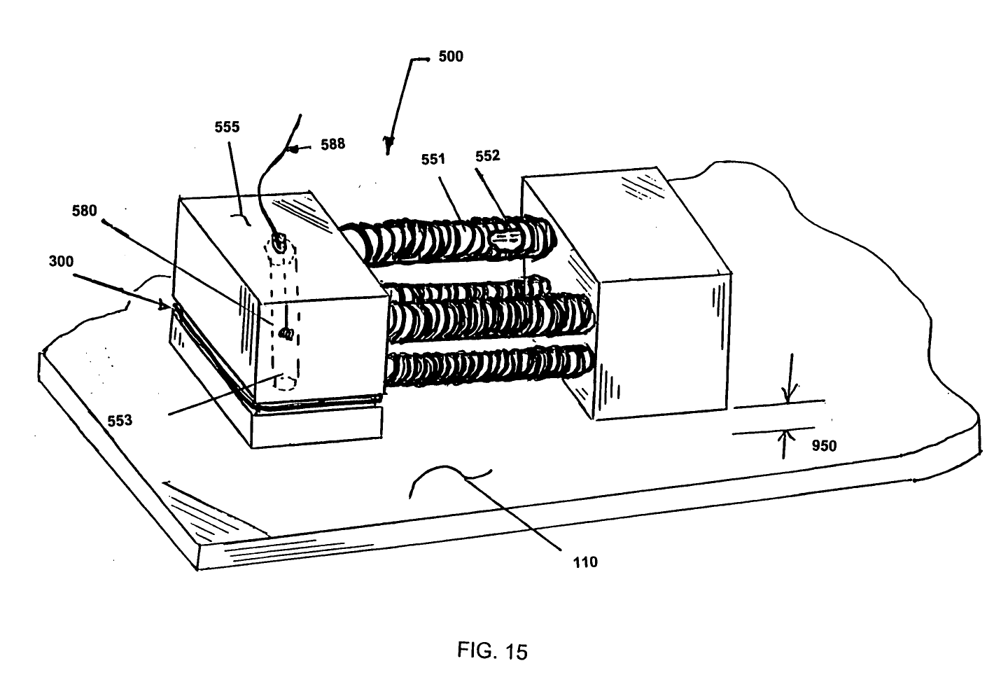

FIG. 14 is a graph of amplitude versus time for a bistatic configured saturation flux generator of the present invention. The frequency is held constant (fixed) and the metal, also of constant thickness, and is varied. The bistatic saturation flux generator was nulled using copper 902. Thereafter, the copper was replaced with brass causing the amplitude to vary from the original nulled position 904 to a new position 904. Since brass and copper have related properties, the dislocation 904 from the copper nulled position 902 is small. However, when the brass is replaced with aluminum the amplitude 906 varies significantly from the original nulled position 902. Aluminum and copper have significantly different physical characteristics.

### Method of Procedure

As the apparatus of the invention traverses the surface of the coated metal, a number of procedures are carried out in the following manner at a particular point.

The permeability of the material at the target location is measured by varying the “H” field by increasing the magnetic coils current by fixed amounts.

The conductivity of the target material is measured by varying the frequency of the oscillating magnetic flux over some known values.

Using the permeability and conductivity, the thickness of the target material may be calculated.

The automatic lensing algorithm will now measure the resistivity with a particular setting for the transmitter power and the magnetic power.

The resistivity reading is adjusted by the permeability and conductivity values.

The corrected resistivity is corrected to a reference resistivity by comparison to a reference inductor.

The appartus is now ready to move to the next position.

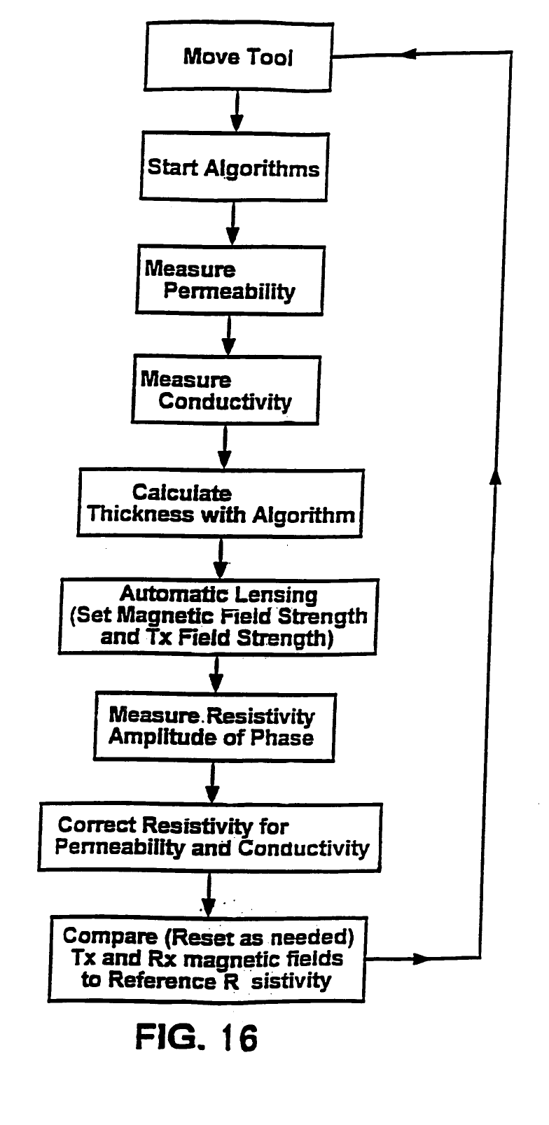

This sequencing is also shown in FIG. 16.

In another embodiment of this invention, a single electrically conductive coil may be used to provide the saturation flux and the transmitter flux. The coil would first be powered with dc current sufficient to create the magnetic flux required for desired amount of saturation of the target material. The power could then be switched to ac current and multiple wavelengths of oscillating magnetic flux be emitted into the target material. The power could then be returned to the dc current providing the saturation flux. This alternating powering could be repeated in rapid succession, thereby conserving power and space and weight requirements for the apparatus. The receiver could also be located proximate to the Metallic Transparency created by the dual functioning saturation and transmitter coil. Accordingly, a separate saturation coil would not be required to create the transparency needed for coupling the oscillating transmitter flux, oscillating within a selected range of frequencies, with the target material. This would provide a further reduction of weight, energy and space. For this embodiment, it will be appreciated that the ac frequency can be controlled and adjusted. It will be appreciated that use of low frequency ac generated magnetic flux will reduce impedance mismatch.

Tests have shown the ability of the invention to achieve accurate measurements of thickness of non magnetically permeable coating material deposited on carbon steel. Additional embodiments of the invention have enhanced this capability. These embodiments have included altering the design or use of certain components and software of the invention. magnetic coupling of the transmitter magnetic field to the metallic surface of the pipe. This has been found to be particularly useful when attempting to direct relatively high frequency oscillating magnetic flux into the target object. However, this circuit required separate components as shown on FIG. 1. The separate components could, in some configurations, include a separate energy source 560 and a ferromagnetic core 552 to concentrate the magnetic flux. This magnetic saturation flux circuit therefore, added bulk and required at least one-quarter amp to energize it.

However, experimentation demonstrated that reducing the permeability of the surface of the target object is less necessary when the surface coating comprises an increasingly thick layer of electrically conductive, but non magnetically permeable material. This is because the surface layer itself has a much reduced permeability and the oscillating magnetic flux from the transmitter coil will couple to the target object (here a coated steel pipe) through this coating.

The separate magnetic flux generator may still be required for the uncoated steel or other ferromagnetic pipe or if it is desired to project the transmitter flux signal deep into the pipe to measure interior defects or deep coatings. In experiments of steel pipe coated with chrome, was reasoned that the chrome coating needed to be in the range of 8 thousands of an inch or greater in thickness to enable the magnetic saturation flux generator to be omitted. However, it was found that software controlling the invention apparatus can be modified to recognize the received signals from pipe that contains less than the 8 mil of coating, including bare steel.

Therefore, in some embodiments of the invention, it has been found beneficial to eliminate the use of a separate saturation flux generator. It will be appreciated that the ability to measure the coating properties without a saturation flux generator has a number of advantages, including but not limited to the savings of weight and electrical power, and reduced bulk.

Another embodiment of the invention utilizes a single coil for both the transmission of oscillating magnetic flux and the receiving the induced oscillating flux from the subject material. This embodiment employs the impact of the induced oscillating flux (sometimes termed “retroflux”) upon the transmitted flux. The impact can be measured by both change of phase or amplitude of the flux. It will be

It will be appreciated that the invention discussed above has utilized multiple sets of components, i.e., one or more saturation flux coils, one or more separate coils for transmitting oscillating magnetic flux and a third set of one or more coils for detecting and receiving induced oscillating magnetic flux. These components are shown in FIG. 1 as a magnetic flux generator 501, (comprising a coil 551 wound around a ferromagnetic core 552), a separate transmitter coil 300 and a separate receiver coil 580. In testing, each of the three coil components were reduced in size from 2 inches until the swept area under the transmitter was approximately one half of an inch. However, it was desired to further reduce the size of these components. Considerations related to this further size reduction were (i) the alignment of the transmitter coil, (ii) the necessity of a separate saturation flux generator coil and core to reduce the permeability of a portion of the target material (in this case, steel pipe coated with an electrically conductive but non magnetically permeable material) and (iii) the need for a separate receiver coil (and circuit) for detecting and measuring induced oscillating magnetic flux.

In regard to the geometrical alignment of the transmitter coil, it was recognized that an orientation of the cylindrical transmitter coil axis perpendicular to the surface of the target object would provide enhanced concentration of the transmitted flux proximate to surface of the material. However, when the target was had a curved surface, e.g., a pipe and the invention was passed across the pipe surface, this orientation was found to be prone to alignment sensitivities due to the close proximity of the device to the uppermost curved surface (“crown”) of the pipe. As the center of the transmitter passed over the crown of the pipe, the phase would change. Therefore, it had been necessary to always shift the center of the transmitter off to one side or the other of the crown. It was found that this alignment, also could pose a problem if the target was of non uniform symmetry or non-cylindrical. In experiments using coated pipe, this “out-of-round” problem did cause reading errors if the readings were to be made near the center of the pipe.

The magnetic saturation flux generator, a separate component supplying a constant or relatively low frequency oscillating electromagnetic energy source to reduce the permeability of the object surface, had been used to provide enhanced appreciated by those skilled in the art that the retroflux bucks the transmitted flux, thereby increasing the impedance of the coil. The relationship to the strength of the retroflux and the change in coil impedance can be used to measure the properties of the target material. The change in coil impedance will alter the phase or amplitude of the total signal engaging with the material.

The use of a single coil again reduces the complexity, size and weight of the device. This embodiment also permits a smaller footprint of the device to the target materials.

Experimentation has also demonstrated an embodiment utilizing a combined transmitter and receiver (hereinafter “transducer”) coil providing enhanced performance when the axis of the transducer coil is aligned parallel to the surface of the target material or, alternatively, the longitudinal axis of the tube or cylinder comprising the target coated material. Advantages of this orientation include, but are not limited to, the position of the transducer with respect to the edge or crown of the tubing having diminished impact upon the measured phase angle of the oscillating magnetic flux.

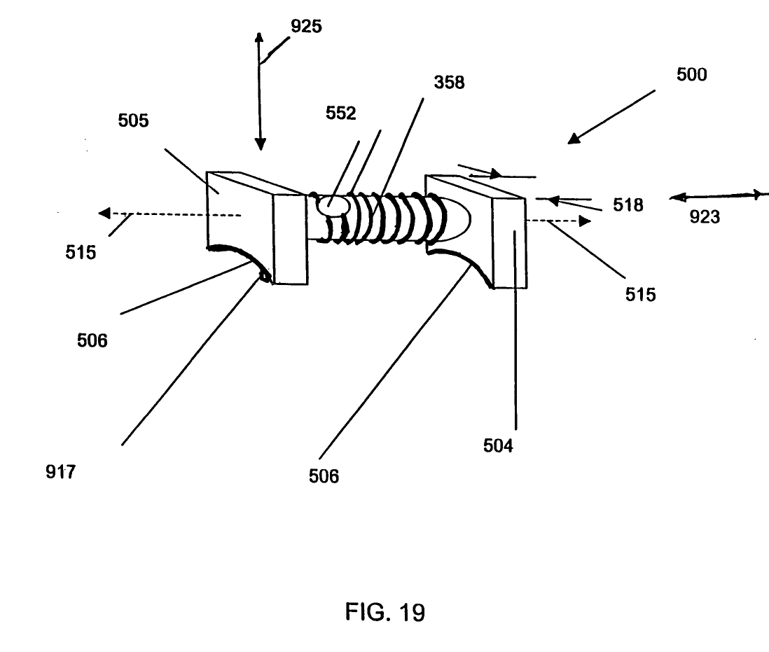

This embodiment is illustrated in FIG. 19. The transducer coil 358 is wound around an electrically conductive and magnetically conductive core material 552. Each end of the core is attached to a highly electrically conductive and magnetically permeable flange 504 and 505 that will each constitute separate magnetic poles when the coil 358 is energized with oscillating electromagnetic energy. Note that the one surface 506 of each pole 504 and 505 proximate to the coated target material may be shaped to approximate the outer surface of the target material. It may also be found advantageous to maintain a constant separation between each surface 506 and the target material by use of non electrically conductive and magnetically permeable spacers 517. Electrically conductive wire 568 and 588 connect the coil 358 to the power supply, amplifier, display panel and other components of the invention.

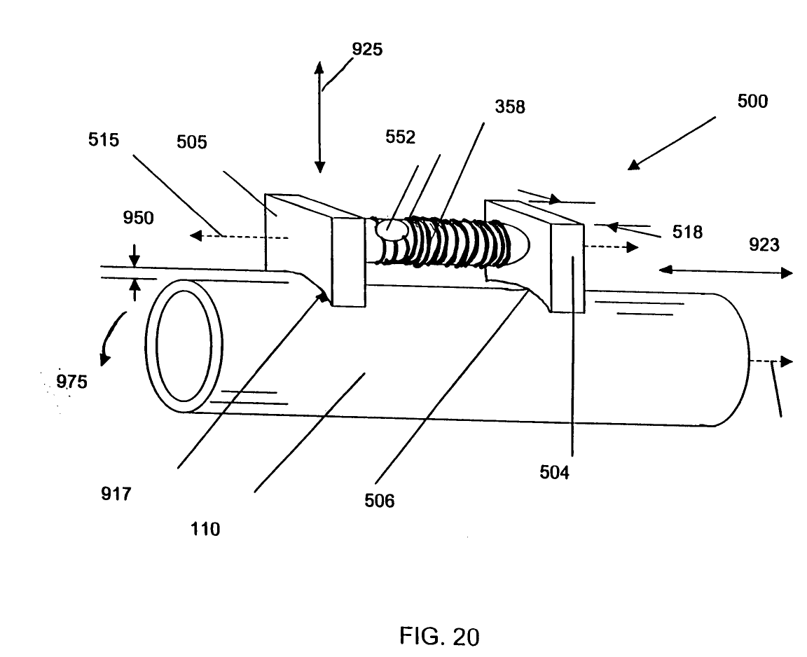

FIG. 20 illustrates the device in conjunction with a tubular target material 110. It will be noted that the either the target material 110 or device 500 may be moved in relation to the other. It has been found useful to have the movement 923 parallel to the axial direction 515 of the transducer coil. The relationship between the width 518 of the pole 504 or 505 can be adjusted or varied to the differing type, shape or composition of the target material 110. A relationship of approximately 20% arc length, being the length of the arc formed by the surface of the flange 506 to the total circumference of the target tube 110 has been found useful. The small percentage relationship allows a detailed surface reading of the coated material. It will also be noted that the space or gap 950 between the target surface and the device pole surface 506 can be maintained constant by use of non conductive spacers or rollers 517.

It will be appreciated by persons skilled in the art that the design of the device 500 illustrated in FIG. 20 also achieve efficiency though the concentrated magnetic flux within the center of the coil 358 being conducted through the core 552 to the flanges 505 and 504 and across the gap 950 to engage the target material 110. These flanges (or end pieces) serve the purpose of bringing the powerful center magnetic flux field generated by the transducer coil down to the surface of the coated pipe. In this manner, the amount of power needed to penetrate the pipe surface is reduced. Without use of the flanges, a significantly smaller portion of the total magnetic flux generated by the transducer coil would be oriented to the surfact of the target object. Of course, it is this quantity of flux that induces the bucking retroflux in the coated target.

Employing the above described modifications, the total footprint of the invention components (501 of FIG. 20) proximate to the target object has been reduced to one half inch wide and three quarters of an inch long. For the target comprising a coated pipe with a diameter of the tubing of one and three quarters of an inch (1.75 inch), the surface of the upper arc of the coated pipe is approximately 2.75 inch, i.e., approximately ½ the circumference of the pipe. The footprint of the transducer is therefore, about 20% of the arc. This small percentage allows a detailed surface reading of the pipe coating

A test jig was built that allowed movement in three degrees of freedom with vernier accuracy. The transducer was mounted on a vertical 925 movement track that allowed it to be repeatedly lowered to the exact location (where the distance or gap 950 between the bottom surface 506 of the transducer flange 504-505 and the target coated pipe 110 is constant for each reading) near the surface of steel pipe coated with chrome. The coated pipe was placed on the tray that could move the pipe horizontally 923 under the transducer 500. The crown of the pipe (the “uppermost” portion of the curved pipe surface) was located below a micrometer attached to the vertical track's holder.

When the micrometer indicated the center of the crown was directly under the transducer, and it was the uniform distance vertically above the crown for all test readings, a reading was taken.

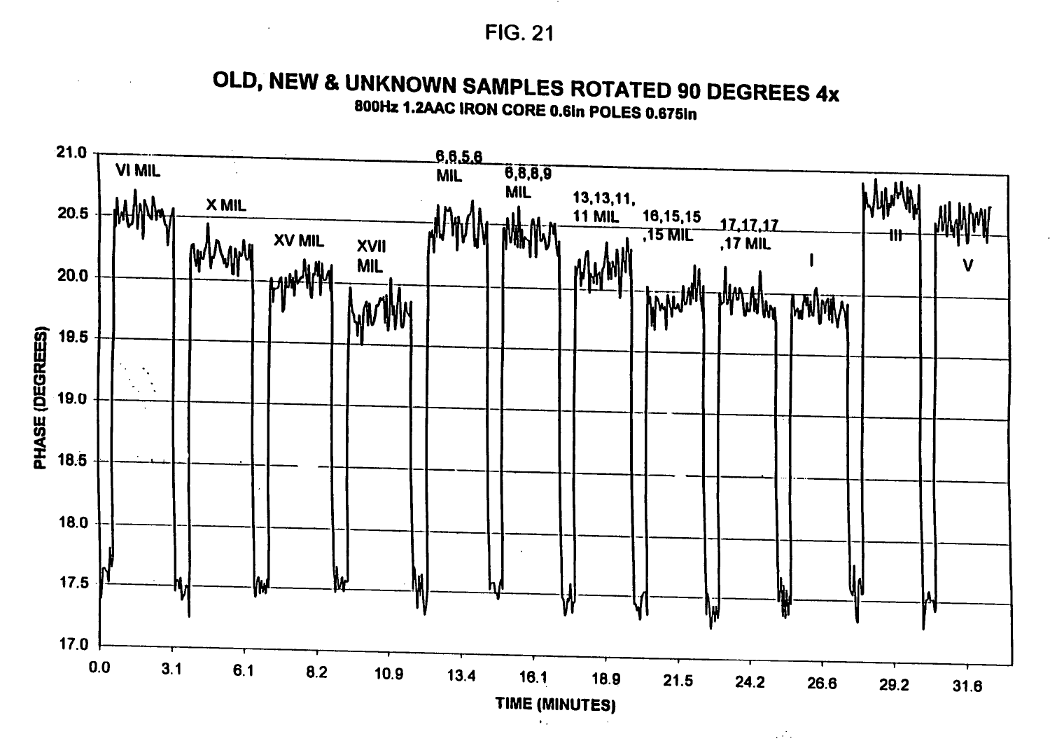

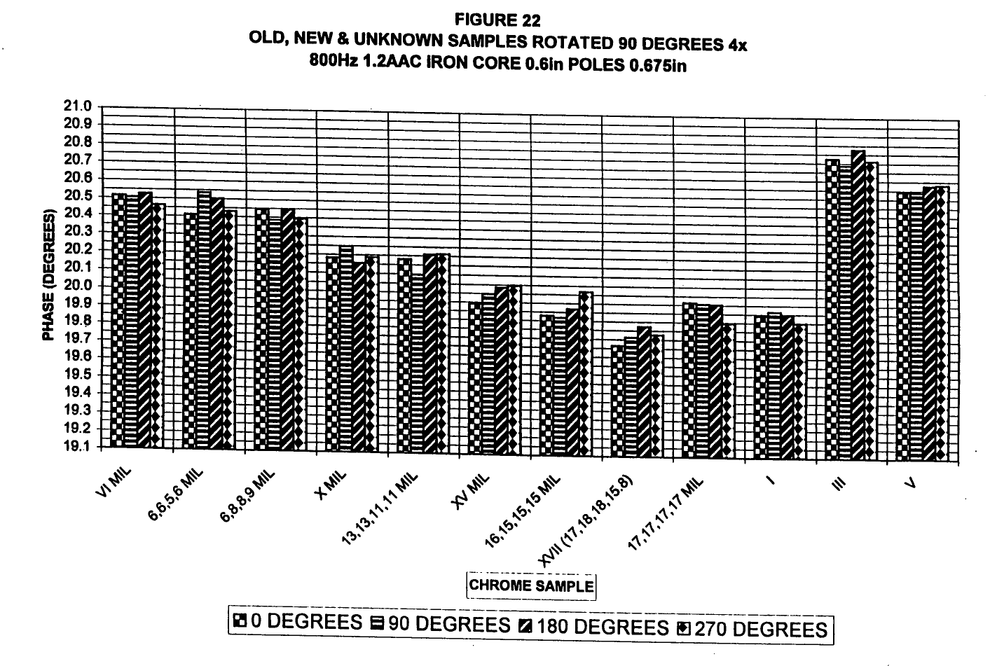

The power and frequency of the oscillating flux transmitted by the transducer could also be varied. It was found that a power setting of 1.2 amps at 10 volts operating at a frequency of 800 Hertz achieved measurements of the coating consistent with the results produced by conventional testing methods. FIG. 21 shows the phase measurements taken of the initial samples of chrome coated pipe, the new standards, and the unknown samples of coated pipe received in raw data form. The Roman numerals represent the initial samples, while the unknowns are labeled as No. 1, No. 3, and No. 5. The samples were rotated 975 90 degrees and measurements were taken. As the samples were removed from the jig, the phase went back down to the reference value (around 17.5 degrees). This reference value is seen to drift by a few tenths of a degree, which is one of the “noise” elements on the readings before any averaging is done. The drift is later removed from the final value of the phase by a normalizing algorithm, a moving average (10 to 20 data points) is made, and the results are plotted as a bar chart in FIG. 22.

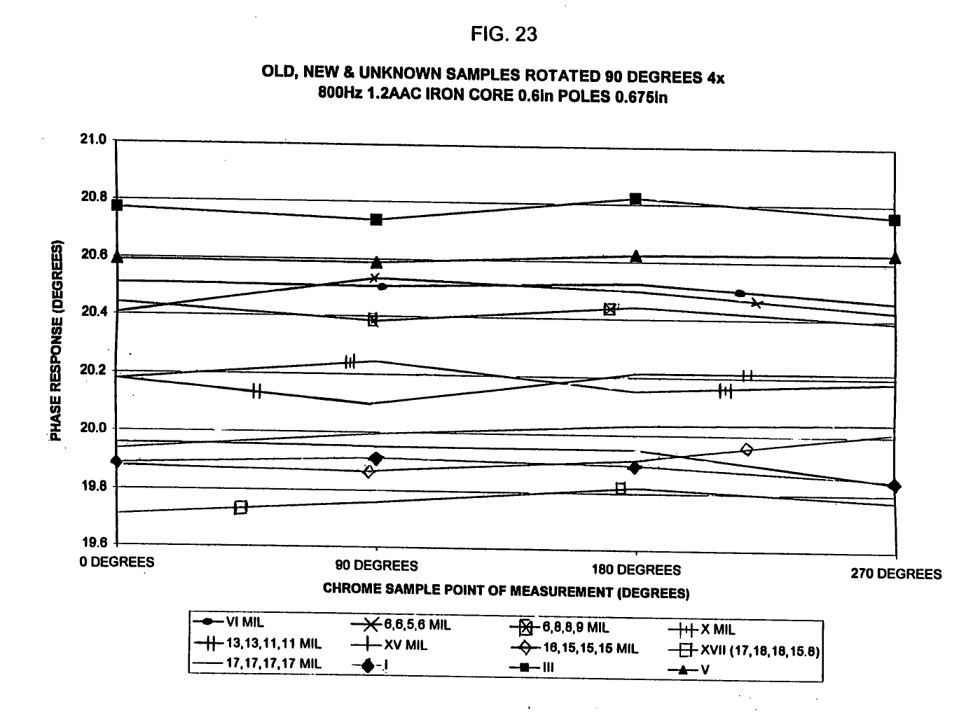

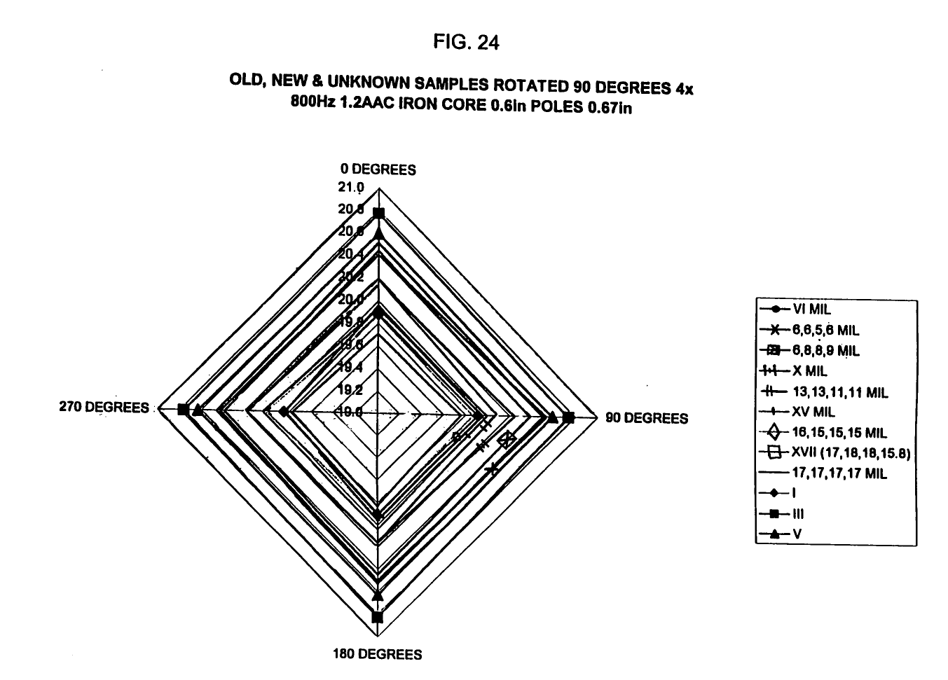

FIG. 23 and FIG. 24 show the unknown samples and known samples plotted in a form that may be better understood from a topological viewpoint.

In comparing the unknown samples with the two sets of known samples, it is seen from FIG. 21 that the unknown sample No. 1 has a rough average value between the old sample value of XV mils and the new sample value of 17 mils. It will be noted that as the chrome layer is increased, there is a corresponding diminished difference between the signatures. Thus, the signal has an asymptotic value. This means that at these values of amperage and frequency there will be a maximum thickness of chrome beyond which the phase will cease to vary. For such thick coating samples, it may be advantageous to lower the transducer signal frequency to achieve increased depth of penetration into the chrome. At 800 Hertz and 1.2 amps, the maximum detectable chrome deposition thickness may be approximately 24 mils.

The data further shows that unknown sample No. 3 has less chrome on it than either the VI mils of the initial samples or the 6 mils of the new samples. Since the applicant did not have a reference sample coated with this amount of chrome deposition, it was estimated by simple extrapolation that the coating deposition was approximately 2 to 3.5 mils. Similarly with unknown sample No. 5; it falls below any reference indication of either the initial samples or the new reference samples. However, again by extrapolation, it was estimated that the chrome coating thickness averaged between 3.5 to 5 mils.

It was a goal of testing this embodiment of the invention to demonstrate the ability to determine or identify samples of chrome coated pipe having a coating thickness of below 8 mils. The oscillating frequency of the flux transmitted by the transducer in this embodiment was increased from 4 kilohertz to 15 kilohertz. This allows a faster and more complete electrical and magnetic profile of the samples, better resolution.

UNKNOWN SAMPLE No. 1 VALUES

| Position | Average Chrome Thickness |
|---|---|
| 0° | 15.75 mils |
| 90° | 15.67 mils |
| 180° | 16.09 mils |
| 270° | 16.19 mils |

By the nature of these EM measurements, it should be noted that the exact correlation with traditional destructive microscopic thickness measurement at a single point may not be achieved. The eddy currents that are induced into the coating at a single transducer position with the target are conducted throughout the electrically conductive material and even to the end of material. Yet the average value of these induced eddies at the transducer is dominated by the effect at the footprint area. Further, the average of measurements achieved by the invention correlate consistently to the thickness measurements taken at each of the points by conventional methods. Therefore, the invention has achieved a method and apparatus for remote, i.e., non-contacting, measurement of electrically conductive thickness coating material on a substrate.

Additional embodiments of the invention have been utilized to achieve enhanced accuracy of measurement of electrically conductive, non magnetically permeable coating on a ferromagnetic substrate. It has been found that the magnetic permeability of a ferromagnetic pipe sample can vary up to 20 percent along the axial length of the sample. A principle reason for this variation of permeability is the variation in heating of the material during manufacture. It was reasoned that the variations in the pipe wall thickness and in the electrical properties of the metal could be minimized by focusing the magnetic signal into the non magnetically permeable coating. This could be accomplished by increasing the frequency of the transducer signal.

First, it will be appreciated by those skilled in the art that like charges on a conductor will repel each other. This repulsion causes the charges to travel to the surface of the metal conductor, leaving the interior of the conductive metal relatively free of a net charge. This surface charge distribution will be accentuated as the quantity of charge is increased or the voltage on the charge is increased.

In addition, if the charge is induced from an external oscillating magnetic field, i.e., a magnetic field above but proximate to the surface, the depth of penetration of this external magnetic field from the surface is governed by the skin depth formula. These two effects may be expressed by the following basic formulas,

Repulsion force≅(Q₁×Q₂)/R² (1)

Skin depth≅1/(μ×μᵣ×σ×f)^{1/2} (2)

where Q: charge

R: distance between charges

μ (mu): absolute permeability value

μᵣ: relative permeability value

σ (sigma): electrical conductivity

f (freq): transmitter frequency

In equation 1 it is seen that by increasing the charge Q, the repulsion force increases thus concentrating the currents toward the surface of the ferromagnetic pipe. Likewise in equation 2, increasing the frequency also reduces the depth of penetration of the oscillating signal, thereby limiting the quantity of energy available to induce eddy currents within the interior of the pipe material. Therefore the relatively distribution of induced eddy currents will be more concentrated within the coating at the surface of the pipe. As mentioned above, concentrating the eddy currents on the surface reduces the amount of energy passing through the ferromagnetic steel of the tubing material. Thus, the underlying characteristics of the ferromagnetic tubing material are minimized.

In earlier tests, transducer frequency of 800 Hertz was used with a power level of 1.2 amps. Due to limitations of the current carrying capacity of the teflon coated wire used for the transducer coil, the focus of testing was on use of higher frequency, i.e., 5000 Hz, 10,000 Hz, and 15,000 Hz.

The transducer was also placed in a more stable platform that allowed the distance of the transducer surface to the coated material to be more closely controlled. This design, illustrated in FIG. 20, achieved a reduced arc of approximately 30° of pipe circumference.

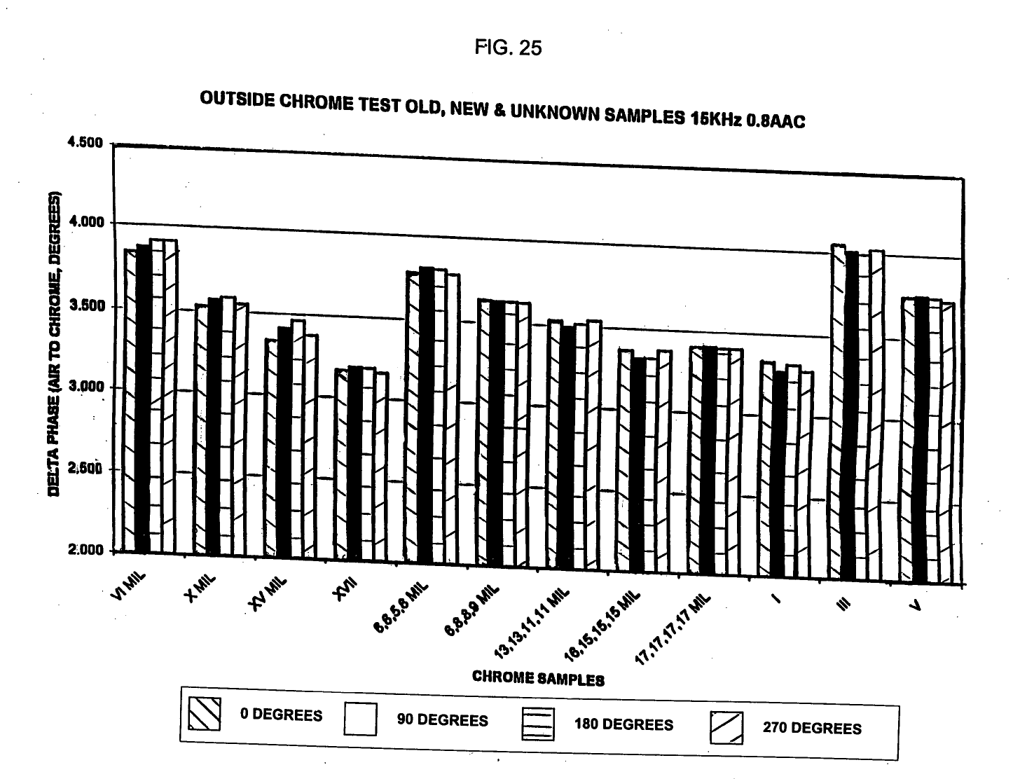

Steel pipe samples coated with chrome were tested using the apparatus of thei invention at the three differing frequencies. It will be appreciated that the data indicates the results of the 15,000 Hz tests with an amperage setting of 0.8 amps provided the best performance. (See FIG. 25) A review of the data in the attached figures provides interesting adjustments to the earlier results, as follows:

1. Unknown sample No. 1 test results did not significantly change as a result of using the higher frequency. When compared to the newer references, the measured valuse were within the range of the 16 mil and 17 mil references. However, all four positions on the 17 mil sample now show up at equal values, which better corresponds to the given measured values.)

2. Unknown sample No. 3 test results were found much closer to the known samples of 6 mils (or VI mil in the first reference). Thus, the chrome coating was estimated to be 4.5 to 5 mils by extrapolation from FIG. 25. From earlier test results, the thickness had been estimated to be between 2 mils and 3.5 mils.

3. Unknown sample No. 5 test results were now found to be within both the old references, VI mil and X mil, and the newer references, 6 mil and 8 mil, and may be estimated at 7.5 mils. It is noted that this is quite uniform for the 4 measurement positions.

The following table indicates the revised calculations of the chrome thickness for each quadrant.

TABLE OF CHROME THICKNESS FOR
UNKNOWN SAMPLES (Revised)

| | Average Chrome Thickness | | |
|---|---|---|---|
| Position | Sample No. 1 | Sample No. 3 | Sample No. 5 |
| 0° | 16.0 mils | | 7.5 mils |
| 90° | 16.5 mils | Approximately | 7.3 mils |
| 180° | 16.1 mils | 4.5 to 5.0 mils | 7.7 mils |
| 270° | 16.5 mils | 7.9 mils | |

The combination of changes in the transmitter frequency and improvements in the fixed standoff distance of the sample with respect to the sensor has accounted for a revised thickness measurement, seemingly closer to those measured by conventional destructive test methods.

Further modifications and alternative embodiments of this invention will be apparent to those skilled in the art in view of this specification. Accordingly, this specification is to be construed as illustrative only and is for the purpose of teaching those skilled in the art the manner of carrying out the invention. It is to be understood that the forms of the invention herein shown and describe are to be taken as the presently preferred embodiments. Various changes may be made in the shape, size and arrangement of parts. For example, equivalent elements may be substituted for those illustrated and described herein and certain features of the invention may be utilized independently of the use of other features, all as would be apparent to one skilled in the art after having the benefit of this description of the invention.

What I claim is:

1. An apparatus for measuring the extent a coating material has diffused into a substrate comprising:
a. at least one electrically conductive coil;
b. an ac power supply;
c. a dc power supply;
d. a switch;
e. means to measure electrical reistivity; and
f. means to measure magnetic permeability.

2. A method for measuring the diffusion of a coating material into a substrate comprising:
a. generating a first constant or low frequency magnetic flux;
b. engaging the magnetic flux with a coated material;
c. generating a second magnetic flux containing a plurality of differing magnetic flux oscillating at higher frequencies that the first flux;
d. engaging the higher frequency magnetic flux with the coated material;
e. inducing eddy currents within the coated material;
f. measuring the third separate magnetic flux generated by the eddy currents within the coated material;
g. maintaining a constant level of the first magnetic flux;
h. varying the strength of the second oscillating flux;
i. measuring the change in the amplitude of the of third oscillating flux generated by the eddy currents;
j. varying the strength of the first magnetic flux while maintaining the amplitude of the second oscillating flux constant;
k. measuring frequency of second flux penetrating through the coated material at differing levels of the first flux.
